(19) United States
(12) Patent Application Publication
(10) Pub. No.: US 2026/0076005 A1
(43) Pub. Date: Mar. 12, 2026

(54) DISPLAY DEVICE AND TILED DISPLAY DEVICE

(71) Applicant: InnoLux Corporation, Miao-Li County (TW)

(72) Inventors: Yi-Cheng Tsai, Miao-Li County (TW); Chia-Hao Tsai, Miao-Li County (TW); Yu-Wei Tu, Miao-Li County (TW); Yu-Shih Tsou, Miao-Li County (TW)

(73) Assignee: InnoLux Corporation, Miao-Li County (TW)

(21) Appl. No.: 19/286,213

(22) Filed: Jul. 30, 2025

(30) Foreign Application Priority Data
Sep. 11, 2024 (CN) 202411267362.7

(51) Int. Cl. H10H 29/34; H01L 25/16; H10H 29/30; H10H 29/49; H10K 59/131; H10K 59/18; H10K 59/35

(52) U.S. Cl. CPC H10H 29/345; H10H 29/352; H10H 29/49; H10K 59/131; H10K 59/18; H10K 59/352; H10K 59/353; H10W 90/00

(57) ABSTRACT

A display device includes a first panel having a first display portion. The first panel includes first units disposed in the first display portion. The first unit includes a pixel region including a first sub-pixel region, a second sub-pixel region, a third sub-pixel region, a fourth sub-pixel region, a fifth sub-pixel region and a sixth sub-pixel region, wherein the first sub-pixel region is electrically connected to the second sub-pixel region, the third sub-pixel region is electrically connected to the fourth sub-pixel region, and the fifth sub-pixel region is electrically connected to the sixth sub-pixel region. The first sub-pixel region, the third sub-pixel region and the fifth sub-pixel region have an arrangement sequence in a first direction, and the second sub-pixel region, the fourth sub-pixel region and the sixth sub-pixel region have the arrangement sequence in a direction opposite to the first direction.

### BACKGROUND OF THE DISCLOSURE

### 1. Field of the Disclosure

The present disclosure relates to a display device, and more particularly to a tiled display device.

### 2. Description of the Prior Art

Large transparent display devices can be formed by tiling at least two transparent display panels in which at least a side is borderless. However, in the tiled display device formed by the above-mentioned method, mura phenomenon may be observed at the tiling edge of the tiled display device, thereby affecting the display quality of the tiled display device. Therefore, to improve the display quality of the tiled display device is still an important issue in the present field.

### SUMMARY OF THE DISCLOSURE

The present disclosure aims at providing a display device having an arrangement design of sub-pixel regions and a tiled display device formed through the display device by tiling, thereby reducing the possibility of users observing mura phenomenon at the tiling edge of the tiled display device.

A display device is provided by the present disclosure. The display device includes a first panel having a first display portion. The first panel includes a plurality of first units disposed in the first display portion. At least one of the first units includes a pixel region including a first sub-pixel region, a second sub-pixel region, a third sub-pixel region, a fourth sub-pixel region, a fifth sub-pixel region and a sixth sub-pixel region, wherein the first sub-pixel region is electrically connected to the second sub-pixel region, the third sub-pixel region is electrically connected to the fourth sub-pixel region, and the fifth sub-pixel region is electrically connected to the sixth sub-pixel region. The first sub-pixel region, the third sub-pixel region and the fifth sub-pixel region respectively have at least one light emitting unit, and the second sub-pixel region, the fourth sub-pixel region and the sixth sub-pixel region are spare sub-pixel regions. The first sub-pixel region, the third sub-pixel region and the fifth sub-pixel region have an arrangement sequence in a first direction, and the second sub-pixel region, the fourth sub-pixel region and the sixth sub-pixel region have the arrangement sequence in a direction opposite to the first direction.

A tiled display device is provided by the present disclosure. The tiled display device has a first display portion, a first peripheral portion, a second display portion and a second peripheral portion. The tiled display device includes a plurality of first units disposed in the first display portion and including a first repeating unit, and a plurality of second units disposed in the second display portion and including a second repeating unit. The first repeating unit and the second repeating unit form at least a portion of a repeating unit group, and the first repeating unit and the second repeating unit are located at two sides of a tiling edge of the tiled display device respectively. The tiled display device further includes a first driving circuit board disposed in the first peripheral portion and a second driving circuit board disposed in the second peripheral portion. A plurality of sub-pixel regions in the first repeating unit have a first arrangement, a plurality of sub-pixel regions in the second repeating unit have a second arrangement, and the first arrangement and the second arrangement are rotationally symmetric to each other. The first display portion and the second display portion respectively comprise a plurality of repeating unit groups.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a top view of a display device according to a first embodiment of the present disclosure.

FIG. 2 schematically illustrates a top view of a tiled display device formed by tiling the display device according to the first embodiment of the present disclosure.

FIG. 3 schematically illustrates a partial enlarged top view of a display device according to a variant embodiment of the first embodiment of the present disclosure.

FIG. 4 schematically illustrates a partial enlarged top view of a display device according to another variant embodiment of the first embodiment of the present disclosure.

FIG. 5 schematically illustrates a cross-sectional view of a wire region according to the first embodiment of the present disclosure.

FIG. 6 schematically illustrates a top view of a tiled display device according to a second embodiment of the present disclosure.

FIG. 7 schematically illustrates a top view of a tiled display device according to a third embodiment of the present disclosure.

FIG. 8 schematically illustrates a top view of a tiled display device according to a fourth embodiment of the present disclosure.

FIG. 9 schematically illustrates a top view of a tiled display device according to a fifth embodiment of the present disclosure.

FIG. 10 schematically illustrates a top view of a tiled display device according to a sixth embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale. In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within +10%, +5%, +3%, +2%, +1%, or +0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a display device, a sensing device, a back-light device, an antenna device, a tiled device, a virtual reality product or other suitable electronic devices, but not limited thereto. The electronic device of the present disclosure may be a foldable electronic device, a flexible electronic device or a stretchable electronic device. The display device may include a non-self-emissive display device or a self-emissive display device. The non-self-emissive display device for example includes a liquid crystal display device, but not limited thereto. The self-emissive display device for example includes a light emitting diode display device, but not limited thereto. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, and the like. The diode may include a light emitting diode or a photo diode. The light emitting diode may for example include an organic light emitting diode (OLED) or an inorganic light emitting diode. The inorganic light emitting diode may for example include a mini light emitting diode (mini LED), a micro light emitting diode (micro LED) or a quantum dot light emitting diode (QLED), but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices. The display device is taken as an example of the electronic device for describing the contents of the present disclosure in the following, but the present disclosure is not limited thereto. The electronic device of the present disclosure may be combinations of the above-mentioned devices, such as the combination of display device and other devices, but not limited thereto.

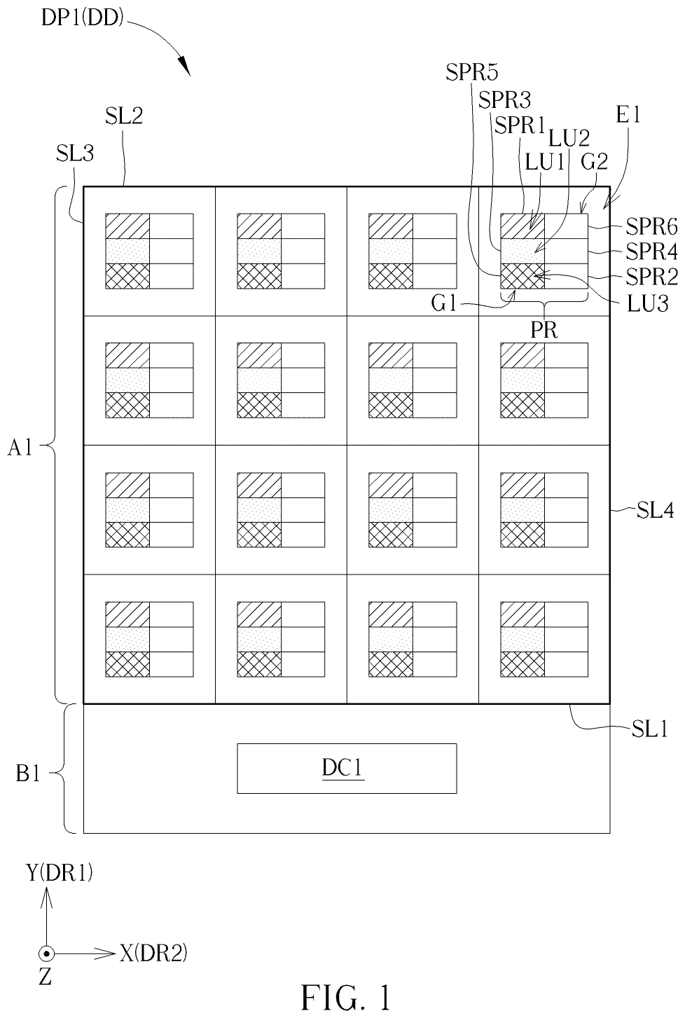

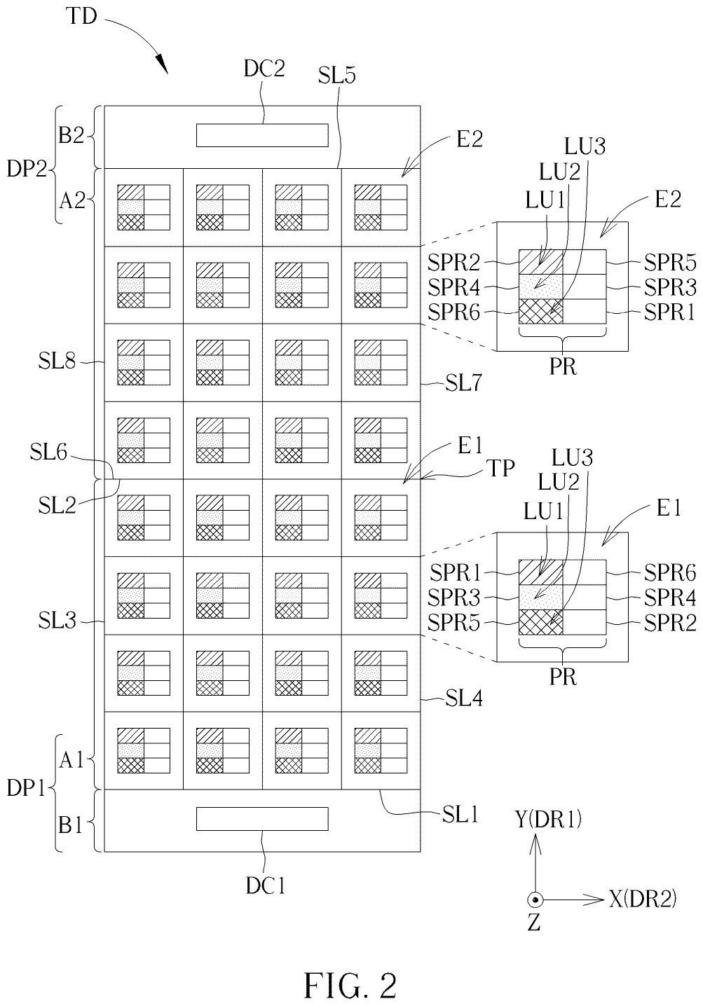

Referring to FIG. 1 and FIG. 2, FIG. 1 schematically illustrates a top view of a display device according to a first embodiment of the present disclosure, and FIG. 2 schematically illustrates a top view of a tiled display device formed by tiling the display device according to the first embodiment of the present disclosure. The display device DD may include a first display panel DP1. The first display panel DP1 may include a self-emissive display panel or a non-self-emissive display panel. The self-emissive display panel for example includes a light emitting diode display panel, and the non-self-emissive display panel for example includes a liquid crystal display panel, but not limited thereto. According to the present embodiment, the first display panel DP1 includes a first display portion A1 and a first peripheral portion B1, the first peripheral portion B1 is disposed on at least a side of the first display portion A1, or the first peripheral portion B1 is disposed along at least a side of the first display portion A1. In addition, the first peripheral portion B1 is not corresponding to at least a side of the first display portion A1, or the first peripheral portion B1 is not disposed on at least a side of the first display portion A1. In other words, the first peripheral portion B1 is not adjacent to at least a side of the first display portion A1. For example, as shown in FIG. 1, in a top view direction of the first display panel DP1 (that is, the direction Z), the first display portion A1 may have a rectangular shape and include a side SL1, a side SL2, a side SL3 and a side SL4, wherein the first peripheral portion B1 may be disposed along the side SL1, but not corresponding to the side SL2, the side SL3 and the side SL4, but not limited thereto. In some embodiments, the first peripheral portion B1 may be disposed along multiple sides of the first display portion A1, such as being disposed along any one, any two or any three of the side SL1, the side SL2, the side SL3 and the side SL4, and the first peripheral portion B1 is not adjacent to at least a side of the first display portion A1. In some embodiments, the first display portion A1 may have any suitable shape in a top view direction of the first display panel DP1, and the first peripheral portion B1 may not be adjacent to at least a portion of an outer edge of the first display panel DP1. The first display portion A1 may be a portion of the first display panel DP1 that is used for mainly displaying images or can be operated by a user, and the first peripheral portion B1 may be used for disposing peripheral elements.

In the present embodiment, multiple display panels may be tiled to form a tiled display device. For example, FIG. 2 shows a tiled display device TD formed by tiling two display panels (that is, the first display panel DP1 and the second display panel DP2), but not limited thereto. According to the present embodiment, in a manufacturing process of the tiled display device TD, the tiled display device TD may be formed by tiling a display panel and another display panel through at least a side of the display portion of the display panel that is not adjacent to (or not corresponding to) the peripheral portion of the display panel (or not provided with the peripheral portion). Specifically, a side of the display portion of a display panel that is not adjacent to its peripheral portion may contact a side of the display portion of another display panel that is not adjacent to its peripheral portion, or the two sides may be adjacent to each other, thereby tiling the two display panels. In such condition, in the tiling process of the display panels, the above-mentioned tiling demands may be achieved by rotating the display panel. For example, as shown in FIG. 2, the tiled display device TD may include a first display panel DP1 and a second display panel DP2, wherein the first display panel DP1 includes a first display portion A1 and a first peripheral portion B1, the second display panel DP2 includes a second display portion A2 and a second peripheral portion B2, and the tiled display device TD may be formed by tiling the first display panel DP1 and the second display panel DP2 by making a side (such as the side SL2) of the first display portion A1 not adjacent to the first peripheral portion B1 contact a side (such as the side SL6) of the second display portion A2 not adjacent to the second peripheral portion B2, or making the side SL2 and the side SL6 adjacent to each other, but not limited thereto. The disposition positions of the second display portion A2 and the second peripheral portion B2 in the second display panel DP2 may refer to the description of the first display panel DP1 mentioned above, but not limited thereto. In some embodiments, the size or disposition position of the second peripheral portion B2 of the second display panel DP2 may be different from the size or disposition position of the first peripheral portion B1 of the first display panel DP1. For example, the second display portion A2 may have a rectangular shape in a top view direction (that is, the direction Z) of the second display panel DP2 and include a side SL5, a side SL6, a side SL7 and a side SL8, wherein the second peripheral portion B2 may be disposed along the side SL5 but not corresponding to the side SL6, the side SL7 and the side SL8, but not limited thereto. In such condition, a tiling edge TP may be included between the first display panel DP1 and the second display panel DP2, and the first peripheral portion B1 and the second peripheral portion B2 may not be disposed corresponding to the tiling edge TP. That is, in a top view direction of the tiled display device TD (that is, the direction Z), the first peripheral portion B1 and the second peripheral portion B2 are not overlapped with the tiling edge TP. The tiling edge TP may for example be a side (that is, the side SL2) of the first display panel DP1 used for tiling other display panels or a side (that is, the side SL6) of the second display panel DP2 used for tiling other display panels. That is, the first display portion A1 of the first display panel DP1 may be adjacent to or contact the second display portion A2 of the second display panel DP2, and there is no peripheral portion disposed between the first display portion A1 and the second display portion A2. It should be noted that the tiled display device TD may be formed by tiling more than two display panels, which is not limited to what is shown in FIG. 2. Specifically, the sides of a display portion of a display panel that are not adjacent to its peripheral portion may respectively be used for tiling with another display panel. For example, in FIG. 2, the side SL3 and the side SL4 of the first display panel DP1 and the side SL7 and the side SL8 of the second display panel DP2 may be used for tiling with other display panels.

Back to FIG. 1, according to the present embodiment, the first display panel DP1 further includes a plurality of first units E1 disposed in the first display portion A1. The first units E1 may be arranged in an array, for example, the first units E1 in the first display portion A1 may be arranged in a 4*4 array along the direction X and the direction Y in FIG. 1, but not limited thereto. Specifically, the first display portion A1 may be composed of the first units E1 arranged in an array. The number of the first units E1 in the first display portion A1 is not limited to what is shown in FIG. 1. In such condition, the area of the first display portion A1 may be defined through the first units E1. For example, the area of the first display portion A1 may be defined as the area surrounded by the outer edge of the outermost first units E1, but not limited thereto. A first unit E1 may be a pixel unit in the first display portion A1 and may include a pixel region PR. In other words, the first display portion A1 may be composed of pixel units arranged in an array.

According to the present embodiment, the pixel region PR in the first unit E1 may include six sub-pixel regions, which are the sub-pixel region SPR1, the sub-pixel region SPR2, the sub-pixel region SPR3, the sub-pixel region SPR4, the sub-pixel region SPR5 and the sub-pixel region SPR6. The sub-pixel region SPR1 is electrically connected to the sub-pixel region SPR2, the sub-pixel region SPR3 is electrically connected to the sub-pixel region SPR4, and the sub-pixel region SPR5 is electrically connected to the sub-pixel region SPR6. Specifically, the sub-pixel region SPR1 and the sub-pixel region SPR2 are connected in parallel with each other, the sub-pixel region SPR3 and the sub-pixel region SPR4 are connected in parallel with each other, and the sub-pixel region SPR5 and the sub-pixel region SPR6 are connected in parallel with each other. The sub-pixel region SPR1 and the sub-pixel region SPR2 are sub-pixel regions of a first color, wherein one of the sub-pixel region SPR1 and the sub-pixel region SPR2 is a display sub-pixel region of the first color used for displaying a light of the first color, and another one of the sub-pixel region SPR1 and the sub-pixel region SPR2 is a spare sub-pixel region of the first color. Similarly, the sub-pixel region SPR3 and the sub-pixel region SPR4 are sub-pixel regions of a second color, wherein one of the sub-pixel region SPR3 and the sub-pixel region SPR4 is a display sub-pixel region of the second color, and another one of the sub-pixel region SPR3 and the sub-pixel region SPR4 is a spare sub-pixel region of the second color; the sub-pixel region SPR5 and the sub-pixel region SPR6 are sub-pixel regions of a third color, wherein one of the sub-pixel region SPR5 and the sub-pixel region SPR6 is a display sub-pixel region of the third color, and another one of the sub-pixel region SPR5 and the sub-pixel region SPR6 is a spare sub-pixel region of the third color. In the present embodiment, the first color, the second color and the third color may respectively be red, green and blue, but not limited thereto. In other words, the pixel region PR of the first unit E1 may include sub-pixels of three colors, and the sub-pixels of each color may include two sub-pixel regions which are electrically connected (in parallel) to each other. For example, as shown in FIG. 1, the sub-pixel region SPR1, the sub-pixel region SPR3 and the sub-pixel region SPR5 in the pixel region PR may be display sub-pixel regions, such as the red display sub-pixel region, the green display sub-pixel region and the blue display sub-pixel region respectively, and the sub-pixel region SPR2, the sub-pixel region SPR4 and the sub-pixel region SPR6 in the pixel region PR may be spare sub-pixel regions, such as the red spare sub-pixel region, the green spare sub-pixel region and the blue spare sub-pixel region, but not limited thereto.

In the above situation, the sub-pixel region SPR1, the sub-pixel region SPR3 and the sub-pixel region SPR5 respectively have at least one light emitting unit, or the light emitting units can be disposed corresponding to the sub-pixel region SPR1, the sub-pixel region SPR3 and the sub-pixel region SPR5. For example, as shown in FIG. 1, the sub-pixel region SPR1 may have a light emitting unit LU1, the sub-pixel region SPR3 may have a light emitting unit LU2, and the sub-pixel region SPR5 may have a light emitting unit LU3. The light emitting unit may include a light emitting diode, but not limited thereto. The light emitting diode may include an organic light emitting diode (OLED) or an inorganic light emitting diode. The inorganic light emitting diode may include a mini light emitting diode, a micro light emitting diode or a quantum dot light emitting diode. The light emitting unit may not be disposed corresponding to the spare sub-pixel regions (such as the sub-pixel region SPR2, the sub-pixel region SPR4 and the sub-pixel region SPR6). It should be noted that although the light emitting unit is not disposed corresponding to the spare sub-pixel regions, the color of a spare sub-pixel region may be determined according to the display sub-pixel region to which the spare sub-pixel region is electrically connected. In some embodiments, the light emitting unit LU1, the light emitting unit LU2 and the light emitting unit LU3 may respectively emit red light, green light and blue light, such that the sub-pixel region SPR1, the sub-pixel region SPR3 and the sub-pixel region SPR5 may respectively display red light, green light and blue light. In some other embodiments, the light emitting unit LU1, the light emitting unit LU2 and the light emitting unit LU3 may emit lights of the same color, such as blue light, and the first display panel DP1 may further include light converting layers disposed respectively corresponding to the sub-pixel region SPR1 and the sub-pixel region SPR3, which are used for converting the lights into red light and green light. It should be noted that the disposition positions of the display sub-pixel regions in the pixel region PR are not limited to what is shown in FIG. 1. In some embodiments, as shown in the second display panel DP2 in FIG. 2, the sub-pixel region SPR2, the sub-pixel region SPR4 and the sub-pixel region SPR6 may be display sub-pixel regions, such as the red display sub-pixel region, the green display sub-pixel region and the blue display sub-pixel region respectively, and the sub-pixel region SPR1, the sub-pixel region SPR3 and the sub-pixel region SPR5 may be spare sub-pixel regions, such as the red spare sub-pixel region, the green spare sub-pixel region and the blue spare sub-pixel region respectively. In some embodiments, any one of the sub-pixel region SPR1 and the sub-pixel region SPR2, any one of the sub-pixel region SPR3 and the sub-pixel region SPR4, and any one of the sub-pixel region SPR5 and the sub-pixel region SPR6 may be selected as the display sub-pixel regions. In some embodiments, the light emitting unit may be disposed in both the sub-pixel region SPR1 and the sub-pixel region SPR2, and the brightness of the light emitting unit corresponding to the sub-pixel region SPR1 may be the same as or different from the brightness of the light emitting unit corresponding to the sub-pixel region SPR2. Similarly, the light emitting unit may be disposed in both the sub-pixel region SPR3 and the sub-pixel region SPR4, and the brightness of the light emitting unit corresponding to the sub-pixel region SPR3 may be the same as or different from the brightness of the light emitting unit corresponding to the sub-pixel region SPR4; the light emitting unit may be disposed in both the sub-pixel region SPR5 and the sub-pixel region SPR6, and the brightness of the light emitting unit corresponding to the sub-pixel region SPR5 may be the same as or different from the brightness of the light emitting unit corresponding to the sub-pixel region SPR6. In the present embodiment, the sizes of the sub-pixel regions of different colors may be the same or different. For example, the size of the sub-pixel region SPR1 (or the sub-pixel region SPR2), the size of the sub-pixel region SPR3 (or the sub-pixel region SPR4), and the size of the sub-pixel region SPR5 (or the sub-pixel region SPR6) may be the same or different. In addition, in a pixel region PR, the sizes of the two sub-pixel regions of the same color may be the same. For example, the size of the sub-pixel region SPR1 may be the same as the size of the sub-pixel region SPR2, the size of the sub-pixel region SPR3 may be the same as the size of the sub-pixel region SPR4, and the size of the sub-pixel region SPR5 may be the same as the size of the sub-pixel region SPR6. “The size of the sub-pixel region” mentioned above may for example be the area of the sub-pixel region in a top view direction of the display panel (or the tiled display device TD), but not limited thereto.

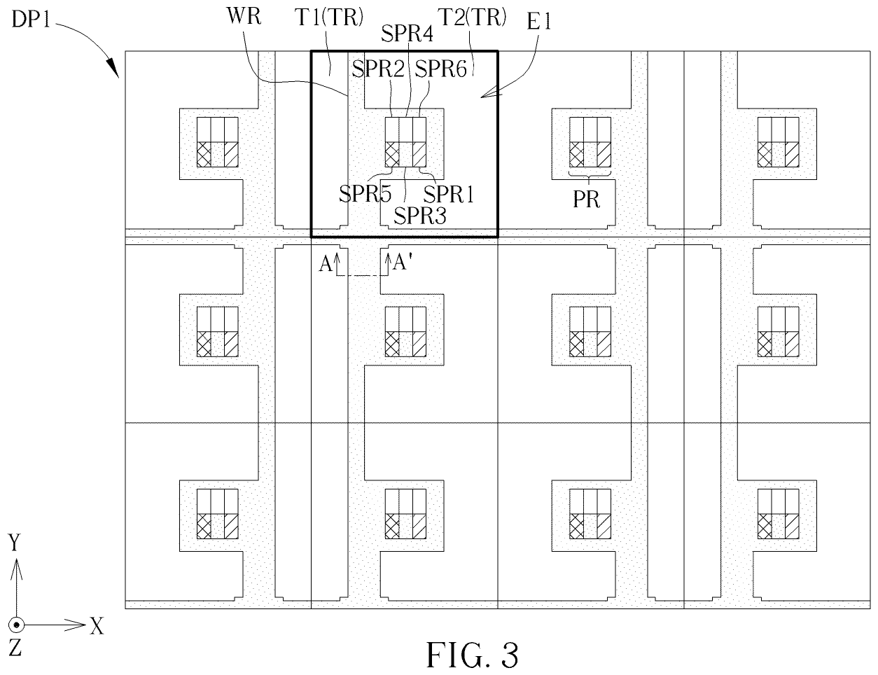

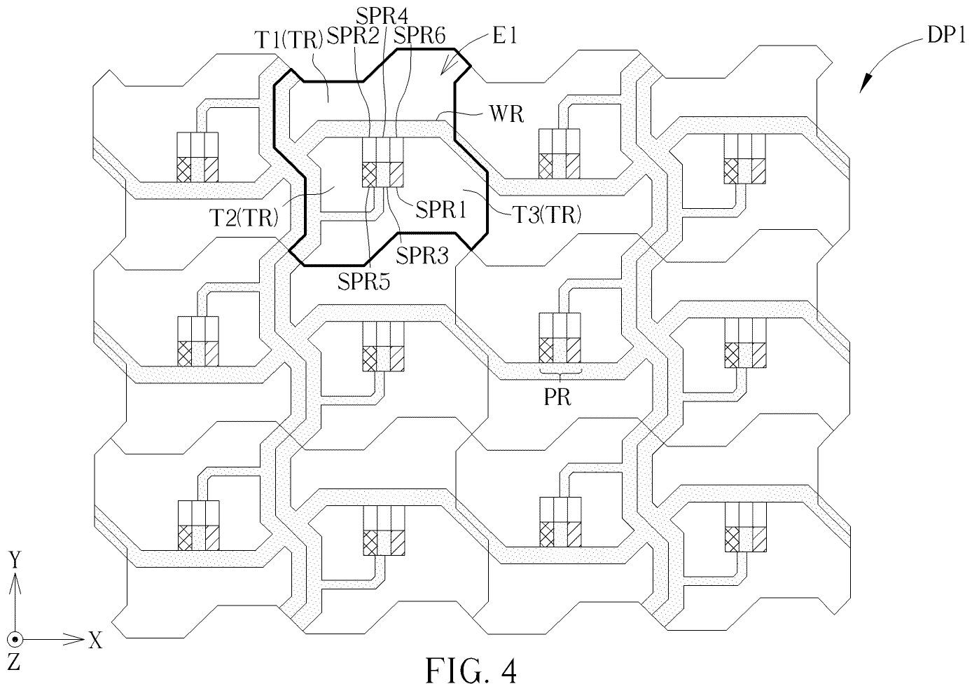

According to the present embodiment, the first sub-pixel region SPR1, the sub-pixel region SPR3 and the sub-pixel region SPR5 have an arrangement sequence (or an arrangement way) in a first direction DR1, and the sub-pixel region SPR2, the sub-pixel region SPR4 and the sub-pixel region SPR6 have the arrangement sequence (or the arrangement way) in another direction opposite to the first direction DR1. “The arrangement sequence (or the arrangement way) of the sub-pixel regions” described herein may for example represent the order of arrangement of the sub-pixel regions. For example, as shown in FIG. 1, the sub-pixel region SPR5, the sub-pixel region SPR3 and the sub-pixel region SPR1 may be sequentially arranged along the first direction DR1, and the sub-pixel region SPR6, the sub-pixel region SPR4 and the sub-pixel region SPR2 respectively be electrically connected to the sub-pixel region SPR5, the sub-pixel region SPR3 and the sub-pixel region SPR1 may be sequentially arranged along a direction opposite to the first direction DR1. In the present embodiment, the first direction DR1 may be the direction Y, that is, the sub-pixel region SPR5, the sub-pixel region SPR3 and the sub-pixel region SPR1 are sequentially arranged along the direction Y, and the sub-pixel region SPR6, the sub-pixel region SPR4 and the sub-pixel region SPR2 are sequentially arranged along the direction-Y. That is, the arranging direction of the sub-pixel region SPR1, the sub-pixel region SPR3 and the sub-pixel region SPR5 is opposite to the arranging direction of the sub-pixel region SPR2, the sub-pixel region SPR4 and the sub-pixel region SPR6. In addition, in a second direction DR2 (that is, the direction X) perpendicular to the first direction DR1, the sub-pixel region SPR1 may be adjacent to the sub-pixel region SPR6, the sub-pixel region SPR2 may be adjacent to the sub-pixel region SPR5, and the sub-pixel region SPR3 may be adjacent to the sub-pixel region SPR4, but not limited thereto. It should be noted that although FIG. 1 shows a structure in which the sub-pixel regions in the pixel region PR are connected to each other, it is not limited in the present embodiment. In some embodiments, the sub-pixel regions in the pixel region PR may be separated from each other. In some embodiments, as shown in FIG. 3 and FIG. 4, the first direction DR1 mentioned above may be the direction X, that is, the sub-pixel region SPR5, the sub-pixel region SPR3 and the sub-pixel region SPR1 may be sequentially arranged along the direction X, and the sub-pixel region SPR6, the sub-pixel region SPR4 and the sub-pixel region SPR2 may be sequentially arranged along the direction-X. It should be noted that “the arrangement sequence (or the arrangement way) of the sub-pixels” described in the present disclosure may for example be determined according to the arrangement sequence (or arrangement way) of the colors of the light emitting units in the sub-pixel regions and the design of the wires in the sub-pixel regions (for determining the spare sub-pixel regions to which the display sub-pixel regions of each color correspond to (or electrically connected to)), which is not limited to the disposition way/arrangement way of the electrodes (such as the p electrode or the n electrode) of the light emitting unit or the bonding pads being bonded to the electrodes. For example, the disposition way/arrangement way of the bonding pads in the sub-pixel region SPR5, the sub-pixel region SPR3 and the sub-pixel region SPR1 used for being bonded to the electrodes of the light emitting units may be the same as or different from the disposition way/arrangement way of the bonding pads in the sub-pixel region SPR6, the sub-pixel region SPR4 and the sub-pixel region SPR2 used for being bonded to the electrodes of the light emitting units. In some embodiments, the bonding pads used for being bonded to the electrodes of the light emitting units in the sub-pixel regions which are electrically connected to each other (for example, the sub-pixel region SPR1 and the sub-pixel region SPR2, the sub-pixel region SPR3 and the sub-pixel region SPR4, or the sub-pixel region SPR5 and the sub-pixel region SPR6) are disposed/arranged in the same way. In some embodiments, the bonding pads used for being bonded to the electrodes of the light emitting units in the sub-pixel regions corresponding to different colors (for example, the sub-pixel region SPR5, the sub-pixel region SPR3 and the sub-pixel region SPR1) are disposed/arranged in the same way or in different ways.

According to the present embodiment through the above-mentioned arrangement design, the arrangement of the sub-pixel regions in the pixel region PR has rotational symmetry. Specifically, the distribution of colors of the sub-pixel regions in the pixel region PR may have rotational symmetry. As shown in FIG. 1, through the above-mentioned arrangement design, two columns of sub-pixel regions may be included in a pixel region PR, that is, a first column of sub-pixel regions G1 located in the left side and a second column of sub-pixel regions G2 located in the right side, wherein the sub-pixel regions in the first column of sub-pixel regions G1 (that is, the sub-pixel region SPR1, the sub-pixel region SPR3 and the sub-pixel region SPR5) have a color order (for example, the order of blue, green and red in the present embodiment, but not limited thereto) in the first direction DR1, and the sub-pixel regions in the second column of sub-pixel regions G2 (that is, the sub-pixel region SPR2, the sub-pixel region SPR4 and the sub-pixel region SPR6) may have the same color order in a direction opposite to the first direction DR1. That is, observed in the same direction, the order of the colors of the sub-pixel regions in the first column of sub-pixel regions G1 may be a reversed order of the order of the colors of the sub-pixel regions in the second column of sub-pixel regions G2. In other words, along the first direction DR1, it can be observed that the sub-pixel regions in the first column of sub-pixel regions G1 are sequentially the blue sub-pixel region (that is, the sub-pixel region SPR5), the green sub-pixel region (that is, the sub-pixel region SPR3), and the red sub-pixel region (that is, the sub-pixel region SPR1), and in an opposite direction of the first direction DR1, it can also be observed that the sub-pixel regions in the second column of sub-pixel regions G2 are sequentially the blue sub-pixel region (that is, the sub-pixel region SPR6), the green sub-pixel region (that is, the sub-pixel region SPR4), and the red sub-pixel region (that is, the sub-pixel region SPR2). In such condition, after the first display panel DP1 shown in FIG. 1 is rotated by 180 degrees, in a pixel region PR, the sub-pixel regions in the second column of sub-pixel regions G2 located in the left side are sequentially the blue sub-pixel region (that is, the sub-pixel region SPR6), the green sub-pixel region (that is, the sub-pixel region SPR4), and the red sub-pixel region (that is, the sub-pixel region SPR2) along the first direction DR1, and the sub-pixel regions in the first column of sub-pixel regions G1 located in the right side are sequentially the blue sub-pixel region (that is, the sub-pixel region SPR5), the green sub-pixel region (that is, the sub-pixel region SPR3), and the red sub-pixel region (that is, the sub-pixel region SPR1) along a direction opposite to the first direction DR1, that is, the color distribution of the sub-pixel regions in a pixel region PR observed after the first display panel DP1 rotates is the same as the color distribution of the sub-pixel regions in the pixel region PR observed before the first display panel DP1 rotates. In short, through the above-mentioned arrangement design of the sub-pixel regions, the arrangement of colors of the sub-pixel regions in a pixel region PR observed before the first display panel DP1 rotates may be the same as the arrangement of colors of the sub-pixel regions in the pixel region PR observed after the first display panel DP1 rotates by 180 degrees, and this situation can be said that the arrangement of the sub-pixel regions has rotational symmetry at a rotation angle of 180 degrees in the present disclosure. It should be noted that in the present embodiment, the arrangement of the sub-pixel regions is not limited to having rotational symmetry only when the rotation angle is 180 degrees. In some embodiments, the arrangement of the sub-pixel regions may have rotational symmetry at a specific rotation angle, wherein the specific rotation angle may be determined according to the rotation situation of the display panels when forming the tiled display device TD, and the specific rotation angle may be greater than 0 degree and less than 360 degrees, such as 90 degrees, 180 degrees or 270 degrees. In addition, the pixel region PR is not limited to including sub-pixels of three colors. In some embodiments, the pixel region PR may include sub-pixels of N colors (N>3), thereby including 2N sub-pixel regions, wherein the arrangement of the 2N sub-pixel regions has rotational symmetry. In some embodiments, the sub-pixel regions may have any suitable arrangement as long as the arrangement of the sub-pixel regions has rotational symmetry at a specific angle. The display panels in the tiled display device TD may all have the arrangement design of the sub-pixel regions mentioned above.

Through the above-mentioned arrangement design of the sub-pixel regions mentioned above, even if the display panels are rotated (tiled after rotation) during the manufacturing process of the tiled display device TD, the arrangement of the sub-pixel regions near the tiling edge TP and the arrangement of the sub-pixel regions in other areas (for example, interior of the display panels) of the tiled display device TD may be substantially the same, thereby reducing mura phenomenon observed at the tiling edge TP. Therefore, the display quality of tiled display device TD may be improved. Specifically, in the present embodiment, a plurality of display panels may be provided at first, and then the display panels may be rotated and tiled to form the tiled display device TD, such that the display portions of different display panels may be tiled with each other through the sides not parallel to the peripheral portions of the display panels. The display panels used for forming the tiled display device TD may all have the above-mentioned design of the sub-pixel regions, but the structures thereof may be the same or different. The tiled display device TD formed through the above-mentioned way may for example include a transparent display device, wherein the front side and the back side of the tiled display device TD allow light to pass through, such that the user may observe the real environment conditions. Since the peripheral portion is not located in the tiling edge TP of the tiled display device TD, the display quality of the tiled display device TD may be improved. In current display panel, if the display panels are rotated and tiled to form a tiled display device, the arrangements of the sub-pixel regions in different display panels may be different from each other due to rotation of the display panels, resulting in the arrangement of the sub-pixel regions near the tiling edge of the tiled display device different from the arrangement of the sub-pixel regions in other areas of the tiled display device. In such condition, the user may observe mura phenomenon at the tiling edge of the tiled display device, thereby affecting the display quality or visual effect of the tiled display device. In contrast, since the arrangements of the sub-pixel regions in the display panels (such as the first display panel DP1 and the second display panel DP2) of the present embodiment have rotational symmetry, the light emitting units may be disposed at proper positions, such that the arrangements of the sub-pixel regions in each area of the tiled display device TD may be substantially the same. For example, as shown in FIG. 2, in a pixel region PR of the first display panel DP1, the light emitting units may be disposed respectively corresponding to the sub-pixel region SPR1, the sub-pixel region SPR3 and the sub-pixel region SPR5, and in a pixel region PR of the second display panel DP2, the light emitting units may be disposed respectively corresponding to the sub-pixel region SPR2, the sub-pixel region SPR4 and the sub-pixel region SPR6. After that, the second display panel DP2 may rotate by 180 degrees, and the first display panel DP1 and the second display panel DP2 may be tiled to form the tiled display device TD by making the side SL6 contact the side SL2 or making the side SL6 adjacent to the side SL2. Therefore, the first peripheral portion B1 and the second peripheral portion B2 may respectively be located at two opposite sides of the tiled display device TD. In such condition, since the arrangement of the sub-pixel regions has rotational symmetry at a rotation angle of 180 degrees, the order of colors of the sub-pixel regions in the two pixel regions PR at two sides of the tiling edge TP of the tiled display device TD and the order of colors of the sub-pixel regions in other areas of the tiled display device TD (for example, in each display panel) in the direction Y may be the same, for example, the color order may be blue, green and red in sequence. That is, the sub-pixel regions in each area of the tiled display device TD may be arranged in the same order of colors. In some embodiments, in a pixel region PR of the first display panel DP1, the light emitting units may be disposed respectively corresponding to the sub-pixel region SPR1, the sub-pixel region SPR4 and the sub-pixel region SPR5, and in a pixel region PR of the second display panel DP2, the light emitting units may be disposed respectively corresponding to the sub-pixel region SPR2, the sub-pixel region SPR3 and the sub-pixel region SPR6, that is, the red display sub-pixel region, the green display sub-pixel region and the blue display sub-pixel region in a pixel region PR may present a pyramid-shaped arrangement (or a triangle-shaped arrangement), and more specifically a “ [symbol] ” shaped arrangement. Therefore, the possibility that the user observes mura phenomenon at the tiling edge TP may be reduced, thereby improving the display quality of the tiled display device TD. In the present embodiment, the rotation angle that makes the arrangement of the sub-pixel regions has rotational symmetry may be determined by the rotation angle of the display panels in the process of rotating and tiling the display panels to form the tiled display device TD. For example, the second display panel DP2 is rotated by 180 degrees and then tiled with the first display panel DP1 to form the tiled display device TD in the present embodiment, and therefore, the arrangement of the sub-pixel regions in the first display panel DP1 and the second display panel DP2 may be designed to have rotational symmetry at a rotation angle of 180 degrees, but not limited thereto.

The tiling way shown in FIG. 2 is just exemplary, and it is not limited in the present embodiment. In some embodiments, the first display panel DP1 and the second display panel DP2 may be tiled to form the tiled display device TD in the way of making the side SL3 contact (or adjacent to) the side SL8 or making the side SL4 contact (or adjacent to) the side SL7. Therefore, the first peripheral portion B1 and the second peripheral portion B2 may be located at the same side of the tiled display device TD, that is, the first peripheral portion B1 is adjacent to the second peripheral portion B2. In such condition, in a pixel region PR of the first display panel DP1 or the second display panel DP2, the light emitting units may be disposed respectively corresponding to the sub-pixel region SPR1, the sub-pixel region SPR3 and the sub-pixel region SPR5, or disposed respectively corresponding to the sub-pixel region SPR2, the sub-pixel region SPR4 and the sub-pixel region SPR6. In some embodiments, the first display panel DP1 and the second display panel DP2 may be tiled to form the tiled display device TD by making the side SL3 contact (or adjacent to) the side SL7 or making the side SL4 contact (or adjacent to) the side SL8. In such condition, the disposition position of the light emitting units in the sub-pixel regions may refer to FIG. 2 and contents mentioned above, and will not be redundantly described.

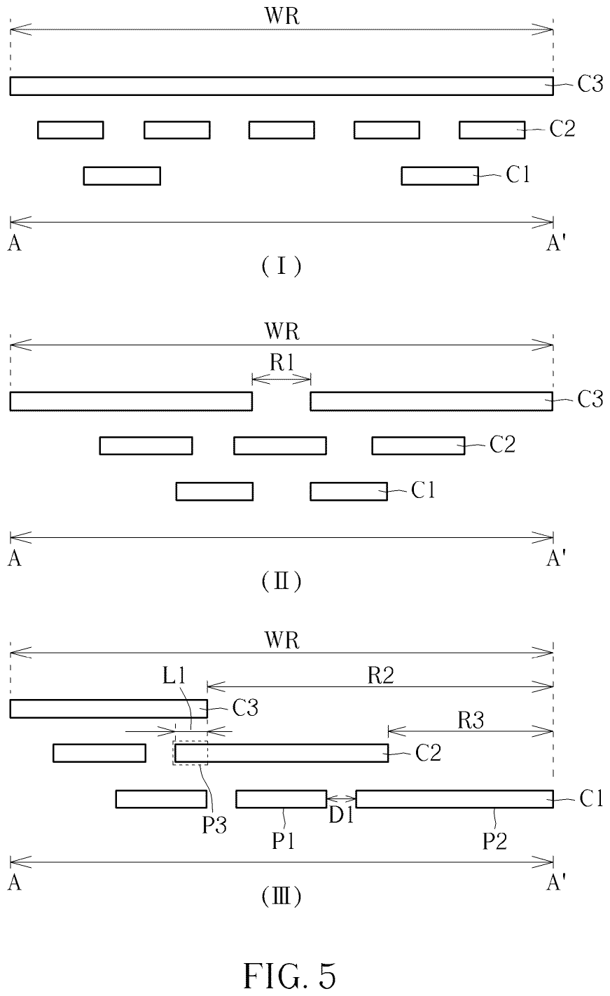

Referring to FIG. 3 to FIG. 5, FIG. 3 schematically illustrates a partial enlarged top view of a display device according to a variant embodiment of the first embodiment of the present disclosure, FIG. 4 schematically illustrates a partial enlarged top view of a display device according to another variant embodiment of the first embodiment of the present disclosure, and FIG. 5 schematically illustrates a cross-sectional view of a wire region according to the first embodiment of the present disclosure. FIG. 3 and FIG. 4 for example show top views of the first units E1 of the first display panel DP1. According to the present embodiment, as shown in FIG. 3 and FIG. 4, the first unit E1 may further include a wire region WR and a transparent region TR in addition to the pixel region PR mentioned above. Specifically, a pixel region PR, a wire region WR and a transparent region TR may be defined in the area of the first unit E1, or the area of the first unit E1 may be composed of the pixel region PR, the wire region WR and the transparent region TR. The wire region WR may be a region corresponding to the signal lines, the active elements, the passive elements or other conductive elements disposed in the first display portion A1 of the first display panel DP1. The signal lines may include scan lines, data lines, power lines, emission lines or other signal lines that can be applied to the first display panel DP1. The active elements may include driving elements, switch elements or other elements that can be applied to the first display panel DP1. The driving element and the switch element for example include thin film transistor (TFT), but not limited thereto. The passive elements may include resistor, capacitor, inductor, and the like, but not limited thereto. Although it is not shown in the figures, in an embodiment, the first display panel DP1 may include a substrate and a circuit layer disposed on the substrate. The circuit layer may include a structure formed by stacking conductive layers and insulating layers, wherein the conductive layers may be used for forming the signal lines, the active elements and the passive elements mentioned above, but not limited thereto. FIG. 5 shows a cross-sectional structure of the structure shown in FIG. 3 along a section line A-A′, that is, FIG. 5 shows a cross-sectional structure of the wire region WR. As shown in FIG. 5, in the present embodiment, the wire region WR may include a first conductive layer C1, a second conductive layer C2 and a third conductive layer C3, wherein the second conductive layer C2 is disposed on the first conductive layer C1, and the third conductive layer C3 is disposed on the second conductive layer C2. The first conductive layer C1, the second conductive layer C2 and the third conductive layer C3 may be the conductive layers in the circuit layer mentioned above, but not limited thereto. In addition, although it is not shown in FIG. 5, insulating layers may be included between the conductive layers, and the first conductive layer C1 may be disposed on a substrate. The first conductive layer C1, the second conductive layer C2 and the third conductive layer C3 may include any suitable conductive material, such as metal materials or transparent conductive materials. The metal material for example includes titanium (Ti), aluminum (Al), molybdenum (Mo), copper (Cu), and the like, but not limited thereto. The transparent conductive material for example includes indium tin oxide (ITO), but not limited thereto. The above-mentioned signal lines, active elements and passive elements disposed corresponding to the wire region WR may be formed by at least one of the first conductive layer C1, the second conductive layer C2 and the third conductive layer C3. For example, in an embodiment, the first conductive layer C1 may form the scan lines and the emission lines, the second conductive layer C2 may form the data lines, and the third conductive layer C3 may form the power lines, but not limited thereto. In an embodiment, the first conductive layer C1 may form the gate electrodes of the driving units and/or the switch elements (TFT elements), and the second conductive layer C2 may form the source electrodes and the drain electrodes of the driving units and/or the switch elements. In some embodiments, the wire region WR may include more conductive layers, which is not limited to what is shown in FIG. 5. In the present embodiment, the light emitting units disposed in the pixel region PR may be electrically connected to the elements disposed in the wire region WR, such as the driving units, such that the diving units may control light emission of the light emitting units. For example, at least one of the signal lines (such as the scan line) in the wire region WR may be electrically connected to a pixel region PR (or a light emitting unit in the pixel region PR) and a driving unit (such as a drain electrode of the driving unit), such that the light emitting unit may be electrically connected to the driving unit, but not limited thereto. In such condition, as shown in FIG. 3 and FIG. 4, the wire region WR may be connected to the pixel region PR in a top view. In addition, in the present embodiment, the driving unit may further be electrically connected to the peripheral elements disposed in the peripheral portion. For example, as shown in FIG. 2, the tiled display device TD may further include a first driving circuit board DC1 disposed in the first peripheral portion B1 of the first display panel DP1 and a second driving circuit board DC2 disposed in the second peripheral portion B2 of the second display panel DP2, wherein the driving units in the first display panel DP1 may be electrically connected to the first driving circuit board DC1, and the driving units in the second display panel DP2 may be electrically connected to the second driving circuit board DC2, but not limited thereto. The first driving circuit board DC1 and the second driving circuit board DC2 may for example include printed circuit boards (PCB), but not limited thereto. It should be noted that although it is not shown in figures, the first display panel DP1 may include other opaque elements in some embodiments, wherein these opaque elements may be disposed corresponding to the wire region WR. In the present embodiment, the transmittance of the wire region WR may be less than 20%, but not limited thereto. In some embodiments, the transmittance of the wire region WR may be less than 15%. In some embodiments, the transmittance of the wire region WR may be less than 10%.

According to the present embodiment, in the area of the first unit E1, the region corresponding to at least one of the conductive layers (such as the first conductive layer C1, the second conductive layer C2 and the third conductive layer C3) used for forming the above-mentioned signal lines, active elements and passive elements may be defined as the wire region WR. In other words, when observing any position in the wire region WR in a top view, at least one of the conductive layers would be observed. FIG. 5 shows several examples of stacking of the conductive layers corresponding to the wire region WR. In some embodiments, as shown in the structure (I) of FIG. 5, the disposition range of the third conductive layer C3 which is the uppermost among the conductive layers may substantially correspond to the range of the wire region WR, or the size (such as area) of the third conductive layer C3 in a top view direction may be substantially the same as the size of the wire region WR in a top view direction. In addition, the first conductive layer C1 and the second conductive layer C2 may be patterned. In other words, the third conductive layer C3 may completely cover the first conductive layer C1 and the second conductive layer C2. In such condition, the third conductive layer C3 may be observed in any position of the wire region WR in a top view. In some embodiments, the third conductive layer C3 which is the uppermost conductive layer may be patterned, such that the third conductive layer C3 is not disposed corresponding to a portion of the wire region WR, and at least one of the first conductive layer C1 and the second conductive layer C2 may be disposed corresponding to the portion of the wire region WR. The first conductive layer C1 and the second conductive layer C2 may be patterned. In other words, the portion of the wire region WR not corresponding to the third conductive layer C3 may still correspond to at least one of the first conductive layer C1 and the second conductive layer C2. For example, as shown in the structure (II) of FIG. 5, the third conductive layer C3 may be patterned and not be disposed corresponding to a region R1 in the wire region WR, but the second conductive layer C2 may be disposed corresponding to the region R1. In such condition, in a top view of the wire region WR, the second conductive layer C2 (at a position corresponding to the region R1) and the third conductive layer C3 (at a position not corresponding to the region R1) may be observed. In some embodiments, as shown in the structure (III) of FIG. 5, the third conductive layer C3 may be patterned and not be disposed corresponding to a region R2 in the wire region WR, the second conductive layer C2 may be patterned and partially correspond to the region R2 such that a region R3 in the wire region WR is not corresponding to the second conductive layer C2 and the third conductive layer C3, and the first conductive layer C1 may be patterned and may correspond to the region R3. In such condition, in a top view of the wire region WR, the third conductive layer C3, the second conductive layer C2 (at a position corresponding to the region R2 but not corresponding to the region R3) and the first conductive layer C1 (at a position corresponding to the region R3) may be observed. It can be known from the above that the range of the wire region WR may be defined by the distribution region of the above-mentioned conductive layers. Specifically, a region corresponding to the union of the orthographic projections of the conductive layers on the X-Y plane (or the substrate) may be the wire region WR, and the area of the region may be the area of the wire region WR.

As mentioned above, the first conductive layer C1, the second conductive layer C2 and the third conductive layer C3 may be patterned, thereby including a plurality of conductive portions. For example, as shown in the structure (III) of FIG. 5, the first conductive layer C1 may be patterned and include a conductive portion P1 and a conductive portion P2 which are separated from and adjacent to each other. According to the present embodiment, a distance D1 may be included between the conductive portion P1 and the conductive portion P2, wherein the distance D1 may be greater than or equal to 0.8 micrometers (μm) (that is, D1≥0.8 μm), but not limited thereto. The distance D1 may be defined as the minimum distance between the conductive portion P1 and the conductive portion P2 in a cross-sectional view of the first display panel DP1 (or the tiled display device TD). In some embodiments, the distance D1 may be greater than or equal to 1 micrometer (that is, D1≥1 μm). In some embodiments, the distance D1 may be greater than or equal to 1.2 micrometers (that is, D1≥1.2 μm). By making the distance D1 fall within the above-mentioned range, the signal interference between different conductive portions in a conductive layer may be reduced, or the problem of short circuit between different conductive portions in a conductive layer caused by falling dust or other objects during the manufacturing process may be reduced. It should be noted that the above-mentioned feature may be applied to any one of the conductive layers, that is, the distance D1 may be the distance between two adjacent conductive portions in any conductive layer.

In addition, in a normal direction of the first display panel DP1 (or the tiled display device TD), a conductive layer may at least partially overlap another conductive layer adjacent to the conductive layer. For example, as shown in the structure (III) of FIG. 5, a portion P3 of the second conductive layer C2 may overlap the third conductive layer C3 which is located above the second conductive layer C2 and adjacent to the second conductive layer C2. According to the present embodiment, in a cross-sectional view of the first display panel DP1 (or the tiled display device TD), the portion P3 may have a length L1, wherein the length L1 may be greater than or equal to 0.1 μm (that is, L1≥0.1 μm). The length L1 may be regarded as the length of the portions of two adjacent conductive layers which are overlapped with each other. In some embodiments, the length L1 may be greater than or equal to 0.2 μm (that is, L1≥0.2 μm). In some embodiments, the length L1 may be greater than or equal to 0.3 μm (that is, L1≥0.3 μm). It should be noted that the above-mentioned feature may be applied to any two adjacent conductive layers. For example, in the structure (III) of FIG. 5, a portion of the second conductive layer C2 may overlap the first conductive layer, and the range of the length of the portion may refer to the range of the length L1 mentioned above. By making the length L1 fall within the above-mentioned range, the possibility of light leakage caused by light being emitted in an oblique direction may be reduced, or the light shielding effect of the conductive layer in an oblique direction may be improved.

It should be noted that the features of the distance D1 and the length L1 mentioned above may also be applied to the structures shown in the structure (I) and the structure (II) of FIG. 5.

Back to FIG. 3 and FIG. 4, according to the present embodiment, the transparent region TR may be defined as other regions in the area of the first unit E1 in addition to the pixel region PR and the wire region WR. The transparent region TR may be adjacent to at least one of the pixel region PR and the wire region WR. According to the layout design of the elements in the wire region WR, the transparent region TR may be divided into a plurality of portions which are separated from each other, but not limited thereto. For example, as shown in FIG. 3, the area of the first unit E1 may include a plurality of transparent portions, that is, the transparent portion T1 and the transparent portion T2, and the combination of the areas of these transparent portions may be the area of the transparent region TR. Similarly, the area of the first unit E1 shown in FIG. 4 may include the transparent portion T1, the transparent portion T2 and the transparent portion T3, and the combination of the areas of these transparent portions may be the area of the transparent region TR. The transparent region TR may correspond to the portion of the first display panel DP1 including transparent materials or high transmittance materials. In the present embodiment, the transmittance of the transparent region TR may be greater than or equal to 20%, but not limited thereto. In some embodiments, the transmittance of the transparent region TR may be greater than or equal to 30%. In some embodiments, the transmittance of the transparent region TR may be greater than or equal to 40%. In addition, according to the present embodiment, the area of the transparent region TR may be greater than 33% of the area of the first unit E1, but not limited thereto. “The area of the transparent region TR and the area of the first unit E1” described herein may for example be the area of the transparent region TR and the area of the first unit E1 in a top view direction respectively. When the transparent region TR includes a plurality of transparent portions, the area of the transparent region TR may be sum of the areas of these transparent portions. For example, the area of the transparent region TR shown in FIG. 3 may be sum of the area of the transparent portion T1 and the area of the transparent portion T2. In some embodiments, the area of the transparent region TR may be greater than 40% of the area of the first unit E1. In some embodiments, the area of the transparent region TR may be greater than 50% of the area of the first unit E1. According to the above-mentioned design, the transmittance of the first unit E1 may be greater than or equal to 30% in the present embodiment, but not limited thereto. In some embodiments, the transmittance of the first unit E1 may be greater than or equal to 40%, 60%, 70% or 80%. In some embodiments, the transmittance of the first unit E1 may be less than or equal to 90%.

In the present embodiment, the shape of the first unit E1 may have rotational symmetry in a top view direction, but not limited thereto. For example, the shape of the first unit E1 shown in FIG. 3 may be a rectangle in a top view direction. Or, the shape of the first unit E1 shown in FIG. 4 may be a windmill or a dart in a top view direction. It should be noted that the shape of the first unit E1 in a top view direction is not limited to what is shown in FIG. 3 and FIG. 4 and may include other shapes having rotational symmetry, such as circle, triangle, regular polygon, and the like, but not limited thereto. In addition, in the present embodiment, the patterns of the wire regions WR and/or the transparent regions TR in different first units E1 in a top view direction may be the same or have rotational symmetry, but not limited thereto. In detail, as shown in FIG. 3 and FIG. 4, the pattern of the wire region WR in a first unit E1 may be the same as the pattern of the wire region WR in another first unit E1 adjacent to the first unit E1 in the direction X after being rotated by 180 degrees. In addition, the pattern of the wire region WR in a first unit E1 may be the same as the pattern of the wire region WR in another first unit E1 adjacent to the first unit E1 in the direction Y. In some embodiments, the wire regions WR in different first units E1 may not have rotational symmetry due to different layouts of signal lines. Similarly, as shown in FIG. 3 and FIG. 4, the pattern of the transparent region TR in a first unit E1 may be the same as the pattern of the transparent region TR in another first unit E1 adjacent to the first unit E1 in the direction X after being rotated by 180 degrees. In addition, the pattern of the transparent region TR in a first unit E1 may be the same as the pattern of the transparent region TR in another first unit E1 adjacent to the first unit E1 in the direction Y. In other words, the first display portion A1 of the first display panel DP1 of the present embodiment may be composed of a plurality of first units E1 which are rotationally symmetric to each other, but not limited thereto. Through the above-mentioned design, after the display panels are rotated and tiled to form the tiled display device TD, the consistency of the structural of the portion of the tiled display device TD near the tiling edge TP and the structure of other portions of the tiled display device TD may be improved, thereby improving the display quality of the tiled display device TD.

It should be noted that the above-mentioned structural features of the first display panel DP1 and the first unit E1 included in the first display panel DP1 may be applied to other display panels (such as the second display panel DP2) in the tiled display device TD. In addition, the above-mentioned structural design and/or size design of the first display panel DP1 shown in FIG. 3 to FIG. 5 may be applied to the embodiments and variant embodiments of the present disclosure.

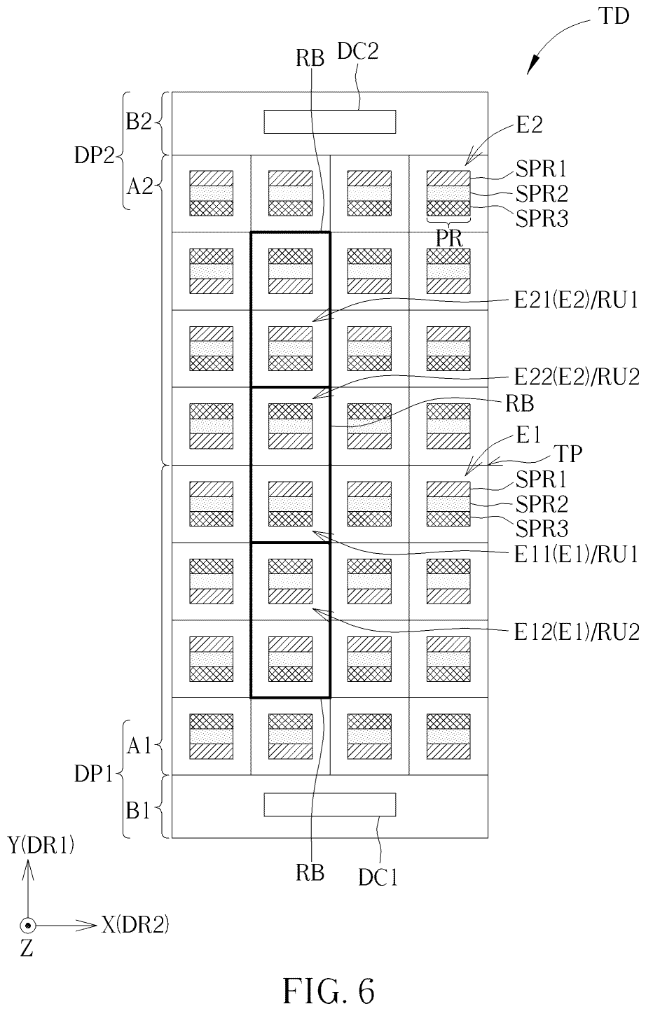

Referring to FIG. 6, FIG. 6 schematically illustrates a top view of a tiled display device according to a second embodiment of the present disclosure. According to the present embodiment, the pixel region PR of the first unit E1 of the first display portion A1 of the display panel (for example, the first display panel DP1) in the tiled display device TD may include three sub-pixel regions, that is, the sub-pixel region SPR1, the sub-pixel region SPR2 and the sub-pixel region SPR3. The sub-pixel region SPR1, the sub-pixel region SPR2 and the sub-pixel region SPR3 may be sub-pixel regions of three colors, such as a red sub-pixel region, a green sub-pixel region and a blue sub-pixel region respectively, but not limited thereto. In some embodiments, the pixel region PR may include more than three sub-pixel regions. According to the present embodiment, the sub-pixel regions in the first unit E1 of the first display panel DP1 may be arranged along the first direction DR1 (such as the direction Y, but not limited thereto). According to the present embodiment, in the first display panel DP1, the sub-pixel regions in each of the pixel regions PR may respectively have a first arrangement (or first arrangement way) or a second arrangement (or second arrangement way). In detail, as shown in FIG. 6, the sub-pixel regions in the pixel region PR of one of the first units E1 (for example, the first unit E11) may have the first arrangement in the first direction DR1 (for example, the direction Y, but not limited thereto). The “first arrangement” described herein may for example represent an arrangement way in which three sub-pixel regions are sequentially a blue sub-pixel region, a green sub-pixel region and a red sub-pixel region along the first direction DR1 (that is, from bottom to top). In addition, the sub-pixel regions in the pixel region PR of another one of the first units E1 (for example, the first unit E12) may have the second arrangement in the first direction DR1 (for example, the direction Y, but not limited thereto). The “second arrangement” described herein may for example represent an arrangement way in which three sub-pixel regions are sequentially a red sub-pixel region, a green sub-pixel region and a blue sub-pixel region along the first direction DR1 (that is, from bottom to top).

According to the present embodiment, the first arrangement and the second arrangement may appear alternately in the plurality of first units E1 of the first display panel DP1 arranged along the first direction DR1. For example, as shown in FIG. 6, the sub-pixel regions in the pixel region PR of the first unit E11 may have the first arrangement, and the sub-pixel regions in the pixel region PR of the first unit E12 adjacent to the first unit E11 in the first direction DR1 may have the second arrangement. In addition, the plurality of first units E1 of the first display panel DP1 arranged along a second direction DR2 (for example, the direction X, but not limited thereto) perpendicular to the first direction DR1 may have the same arrangement. For example, the first units E1 located in the same row as the first unit E11 in the second direction DR2 may all have the first arrangement, and the first units E1 located in the same row as the first unit E12 in the second direction DR2 may all have the second arrangement. In the present embodiment, the first arrangement and the second arrangement may be rotationally symmetric to each other. “The first arrangement and the second arrangement are rotationally symmetric to each other” described herein may include any suitable embodiment in which the order of colors of the plurality of sub-pixel regions having the first arrangement along a direction is the same as the order of colors of the plurality of sub-pixel regions having the second arrangement along the direction after the sub-pixel regions having the first arrangement are rotated at a specific angle. For example, in the present embodiment, after the plurality of sub-pixel regions in the first unit E11 having the first arrangement are rotated by 180 degrees, the order of colors of the sub-pixel regions along the first direction DR1 may be changed to be red, green and blue in sequence, which is the same as the order of colors of the plurality of sub-pixel regions having the second arrangement along the first direction DR1. That is, the first arrangement and the second arrangement are rotationally symmetric to each other at a rotation angle of 180 degrees in the present embodiment. In other words, in the present embodiment, the order of colors of the plurality of sub-pixel regions having the first arrangement along the first direction DR1 may be a reversed order of the order of the colors of the plurality of sub-pixel regions having the second arrangement along the first direction DR1. In this case, the first arrangement and the second arrangement may be mirror-symmetric to each other in the second direction DR2, wherein a surface parallel to the tiling edge TP may serve as a symmetry plane. It should be noted that the rotation angle that makes the first arrangement and the second arrangement rotationally symmetric to each other may be determined according to the rotation angle of the display panels when the display panels are rotated and tiled to form the tiled display device TD. In addition, in the case where the first arrangement and the second arrangement are rotationally symmetric to each other, the first arrangement and the second arrangement may include any suitable arrangement and are not limited to the arrangements mentioned above. The detail of the structure of the first unit E1 in the present embodiment may refer to FIG. 3 to FIG. 5 and related contents above, and will not be redundantly described. The arrangement design of the sub-pixel regions in other display panels (such as the second display panel DP2) of the tiled display device TD may be the same as the arrangement design in the first display panel DP1, and will not be redundantly described.

Through the above-mentioned arrangement design of the sub-pixel regions, after the first display panel DP1 and the second display panel DP2 are rotated (for example, the second display panel DP2 is rotated by 180 degrees) and tiled to form the tiled display device TD, the tiled display device TD may include the first display portion A1 and the first peripheral portion B1 of the first display panel DP1 and the second display portion A2 and the second peripheral portion B2 of the second display panel DP2. The first display portion A1 includes the plurality of first units E1, and the second display portion A2 includes the plurality of second units E2. The structure of the second unit E2 may be the same as the structure of the first unit E1, and the features thereof may refer to the contents mentioned above, which will not be redundantly described. The tiled display device TD may further include the first driving circuit board DC1 disposed in the first peripheral portion B1 and the second driving circuit board DC2 disposed in the second peripheral portion B2. In addition, in the tiled display device TD, the plurality of first units E1 may include a first repeating unit RU1, and the plurality of second units E2 may include a second repeating unit RU2. The sub-pixel regions in the first repeating unit RU1 have the first arrangement mentioned above, and the sub-pixel regions in the second repeating unit RU2 have the second arrangement mentioned above. In other words, the first unit E1 and/or the second unit E2 whose sub-pixel regions have the first arrangement may be regarded as the first repeating unit RU1, and the first unit E1 and/or the second unit E2 whose sub-pixel regions have the second arrangement may be regarded as the second repeating unit RU2. Specifically, the first display portion A1 of the first display panel DP1 includes a plurality of first repeating units RU1 and a plurality of second repeating units RU2, or in other words, the first display portion A1 is composed of the plurality of first repeating units RU1 and the plurality of second repeating units RU2, wherein a first repeating unit RU1 (for example, the first unit E11) is adjacent to a second repeating unit RU2 (for example, the first unit E12) in the first direction DR1. Similarly, the second display portion A2 of the second display panel DP2 includes a plurality of first repeating units RU1 and a plurality of second repeating units RU2, or in other words, the second display portion A2 is composed of the plurality of first repeating units RU1 and the plurality of second repeating units RU2, wherein a first repeating unit RU1 (for example, the second unit E21) is adjacent to a second repeating unit RU2 (for example, the second unit E22) in the first direction DR1. In the present embodiment, a first repeating unit RU1 and a second repeating unit RU2 may be located at two sides of the tiling edge TP of the tiled display device TD respectively, and the first repeating unit RU1 and the second repeating unit RU2 may form at least a portion of a repeating unit group RB. For example, as shown in FIG. 6, a first repeating unit RU1 (for example, the first unit E11) and a second repeating unit RU2 (for example, the second unit E22) respectively be located at two sides of the tiling edge TP of the tiled display device TD may form a repeating unit group RB. The repeating unit group RB may cross the tiling edge TP, or the repeating unit group RB may extend from the first display panel DP1 to the second display panel DP2. According to the present embodiment, the repeating unit group RB may appear repeatedly in the first display portion A1 and the second display portion A2. Specifically, the first display portion A1 and the second display portion A2 respectively include a plurality of repeating unit groups RB (in FIG. 6, only one repeating unit group RB is indicated in the first display portion A1 and the second display portion A2 as an example). In some embodiments, the first display portion A1 and the second display portion A2 may be respectively composed of a plurality of repeating unit groups RB. For example, the repeating unit groups RB may be arranged in an array along the first direction DR1 and the second direction DR2 to form the first display portion A1 and the second display portion A2. In other words, through the arrangement design of the sub-pixel regions mentioned above, the arrangement of the sub-pixel regions near the tiling edge TP may be the same as the arrangement of the sub-pixel regions in other areas (for example, interior of the display panels). Therefore, the situation of mura phenomenon at the tiling edge TP may be reduced, thereby improving the display quality of the tiled display device TD. It should be noted that the detail of the structure of the first units E1 and the second units E2 in the present embodiment may refer to the structure of the first unit E1 in the above-mentioned embodiments, and will not be redundantly described. The structure of the first repeating unit RU1 (or the second repeating unit RU2) may be the same as the structure of the first unit E1 (or the second unit E2), which may also refer to FIG. 3 to FIG. 5 and related contents mentioned above.

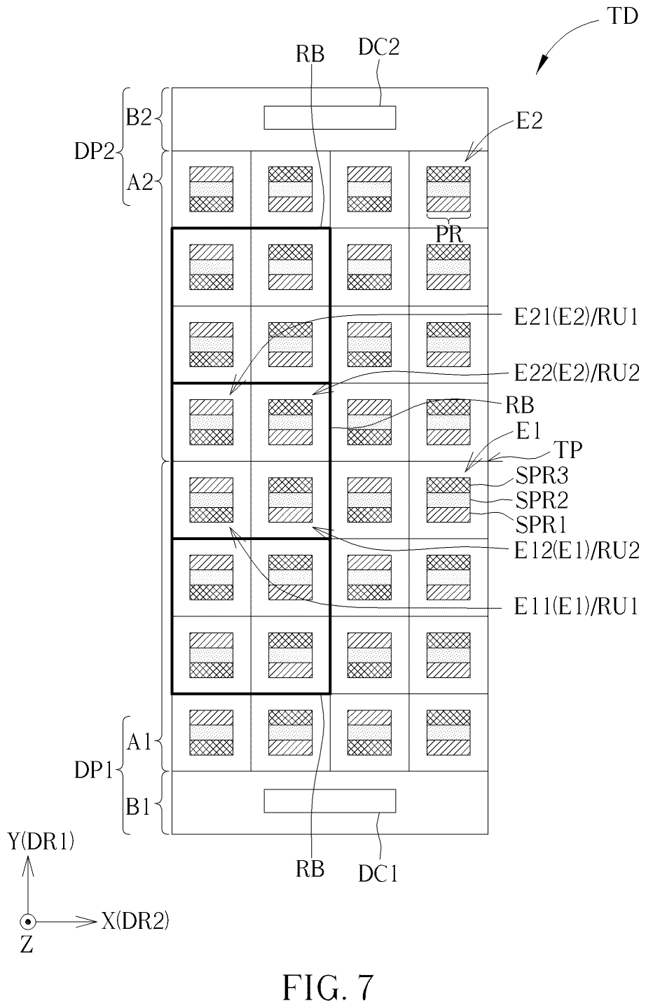

Referring to FIG. 7, FIG. 7 schematically illustrates a top view of a tiled display device according to a third embodiment of the present disclosure. One of the main differences between the display panel of the tiled display device TD of the present embodiment and the display panel of the tiled display device TD shown in FIG. 6 is the arrangement design of the sub-pixel regions. Compared with the embodiment shown in FIG. 6, the first arrangement and the second arrangement may alternately appear in the plurality of first units E1 arranged along the second direction DR2 in the first display panel DP1 of the present embodiment. The details of the first arrangement and the second arrangement may refer to the contents mentioned above, and will not be redundantly described. For example, as shown in FIG. 7, the sub-pixel regions in the pixel region PR of the first unit E11 may have the first arrangement, and the sub-pixel regions in the pixel region PR of the first unit E12 adjacent to the first unit E11 in the second direction DR2 may have the second arrangement. In addition, the plurality of first units E1 arranged along the first direction DR1 in the first display panel DP1 may have the same arrangement. For example, the first units E1 located in the same column as the first unit E11 in the first direction DR1 may all have the first arrangement, and the first units E1 located in the same column as the first unit E12 in the first direction DR1 may all have the second arrangement. The arrangement design of the sub-pixel regions in other display panels (such as the second display panel DP2) of the tiled display device TD may be the same as the arrangement design of the sub-pixel regions in the first display panel DP1, and will not be redundantly described.

Through the arrangement design of the sub-pixel regions mentioned above, after the first display panel DP1 and the second display panel DP2 are rotated (for example, the second display panel DP2 is rotated by 180 degrees, but not limited thereto) and tiled to form the tiled display device TD, the plurality of first units E1 may include a first repeating unit RU1, and the plurality of second units E2 may include a second repeating unit RU2. The definitions of the first repeating unit RU1 and the second repeating unit RU2 may refer to the contents mentioned above. Specifically, the first display portion A1 of the first display panel DP1 includes a plurality of first repeating units RU1 and a plurality of second repeating units RU2, or in other words, the first display portion A1 is composed of the plurality of first repeating units RU1 and the plurality of second repeating units RU2, wherein a first repeating unit RU1 (for example, the first unit E11) is adjacent to a second repeating unit RU2 (for example, the first unit E12) in the second direction DR2. Similarly, the second display portion A2 of the second display panel DP2 includes a plurality of first repeating units RU1 and a plurality of second repeating units RU2, or in other words, the second display portion A2 is composed of the plurality of first repeating units RU1 and the plurality of second repeating units RU2, wherein a first repeating unit RU1 (for example, the second unit E21) is adjacent to a second repeating unit RU2 (for example, the second unit E22) in the second direction DR2. A first repeating unit RU1 and a second repeating unit RU2 may be located at two sides of the tiling edge TP of the tiled display device TD respectively, and the first repeating unit RU1 and the second repeating unit RU2 may form at least a portion of a repeating unit group RB. In detail, as shown in FIG. 7, the repeating unit group RB in the present embodiment may be composed of two first repeating units RU1 and two second repeating units RU2. Specifically, the repeating unit group RB may include two first repeating units RU1 and two second repeating units RU2 arranged in a 2*2 array. For example, the first unit E11, the first unit E12, the second unit E21 and the second unit E22 may form a repeating unit group RB. In such condition, a first repeating unit RU1 (for example, the first unit E11) and a second repeating unit RU2 (for example, the second unit E22) may respectively be located at two sides of the tiling edge TP and may be a portion of the repeating unit group RB. The repeating unit group RB may cross the tiling edge TP, or the repeating unit group RB may extend from the first display panel DP1 to the second display panel DP2. According to the present embodiment, as shown in FIG. 7, the first display portion A1 and the second display portion A2 respectively include a plurality of repeating unit groups RB (in FIG. 7, only one repeating unit group RB is indicated in the first display portion A1 and the second display portion A2 as an example). In some embodiments, the first display portion A1 and the second display portion A2 may be respectively composed of a plurality of repeating unit groups RB. For example, the repeating unit groups RB may be arranged in an array along the first direction DR1 and the second direction DR2 to form the first display portion A1 and the second display portion A2.

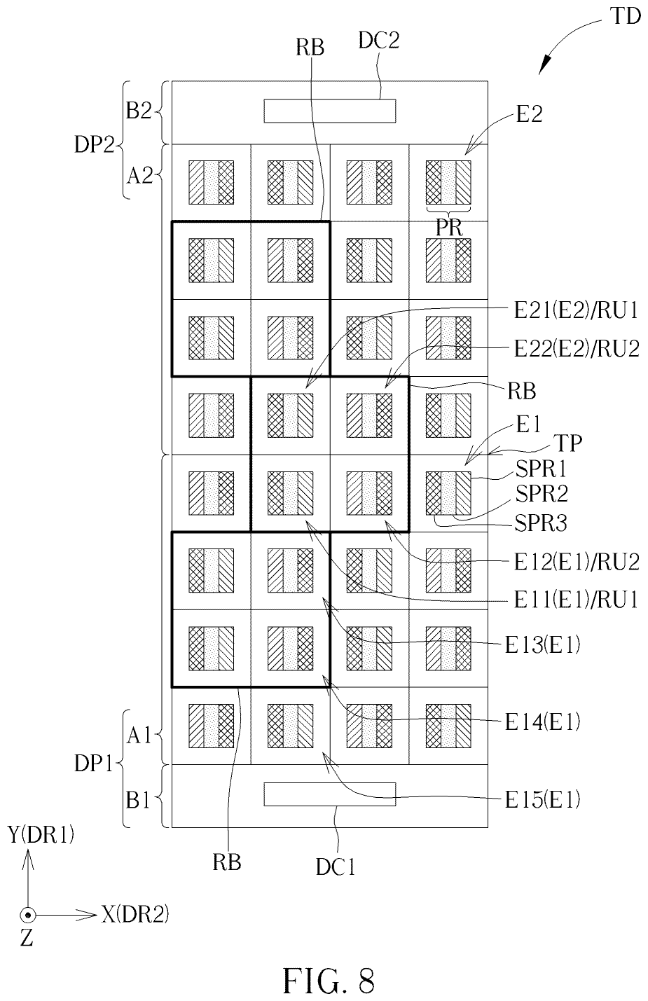

Referring to FIG. 8, FIG. 8 schematically illustrates a top view of a tiled display device according to a fourth embodiment of the present disclosure. One of the main differences between the display panel of the tiled display device TD of the present embodiment and the display panel of the tiled display device TD shown in FIG. 6 is the arrangement design of the sub-pixel regions. In the present embodiment, the sub-pixel regions in the first unit E1 of the first display panel DP1 may be arranged along the second direction DR2 (for example, the direction X, but not limited thereto). In addition, the sub-pixel regions in the pixel regions PR of the first units E1 may respectively have a first arrangement or a second arrangement. For example, as shown in FIG. 8, the first unit E11 in the first display panel DP1 may have the first arrangement, and the first unit E12 in the first display panel DP1 may have the second arrangement. In the present embodiment, the “first arrangement” described herein may for example represent an arrangement way in which three sub-pixel regions are sequentially a blue sub-pixel region, a green sub-pixel region and a red sub-pixel region along the second direction DR2 (that is, from left to right), and the “second arrangement” described herein may for example represent an arrangement way in which three sub-pixel regions are sequentially a red sub-pixel region, a green sub-pixel region and a blue sub-pixel region along the second direction DR2 (that is, from left to right). The first arrangement and the second arrangement may be rotationally symmetric to each other. For example, the first arrangement and the second arrangement may be rotationally symmetric to each other at a rotation angle of 180 degrees. In addition, the first arrangement and the second arrangement may be mirror-symmetric to each other in the first direction DR1 in the present embodiment.

According to the present embodiment, the first arrangement and the second arrangement may alternately appear in the plurality of first units E1 arranged along the second direction DR2 in the first display panel DP1. For example, as shown in FIG. 8, the sub-pixel regions in the pixel region PR of the first unit E11 may have the first arrangement, and the sub-pixel regions in the pixel region PR of the first unit E12 adjacent to the first unit E11 in the second direction DR2 may have the second arrangement. In addition, according to the present embodiment, in the first display panel DP1, a first arrangement order and a second arrangement order may be defined through the arrangements (that is, the first arrangement and the second arrangement mentioned above) of the plurality of first units E1 arranged along the first direction DR1. Specifically, the “first arrangement order” described herein may represent that the arrangements of the sub-pixel regions in two adjacent first units E1 arranged along the first direction DR1 are sequentially the first arrangement and the second arrangement, and the “second arrangement order” described herein may represent that the arrangements of the sub-pixel regions in two adjacent first units E1 arranged along the first direction DR1 are sequentially the second arrangement and the first arrangement. For example, the sub-pixel regions in the first unit E13 and the first unit E11 arranged along the first direction DR1 may sequentially have the second arrangement and the first arrangement, and in this case, it can be defined that the arrangements of the sub-pixel regions in the first unit E13 and the first unit E11 have the second arrangement order. In addition, the sub-pixel regions in the first unit E15 and the first unit E14 arranged along the first direction DR1 may sequentially have the first arrangement and the second arrangement, and in this case, it can be defined that the arrangements of the sub-pixel regions in the first unit E15 and the first unit E14 have the first arrangement order. According to the present embodiment, the arrangements of the plurality of first units E1 arranged along the first direction DR1 may alternately have the first arrangement order and the second arrangement order. For example, as shown in FIG. 8, the arrangements of the sub-pixel regions of the four first units E1 located in the leftmost column in the first display panel DP1 and arranged along the first direction DR1 (from bottom to top) may sequentially have the second arrangement order and the first arrangement order. It should be noted that the number of the first units E1 in the first display panel DP1 shown in FIG. 8 is exemplary, and it is not limited in the present embodiment. In some embodiments, the first display panel DP1 may include more first units E1, and the sub-pixel regions of these first units E1 may be arranged alternately in the second arrangement order and the first arrangement order along the first direction DR1, or arranged alternately in the first arrangement order and the second arrangement order along the first direction DR1. In short, in the present embodiment, the sub-pixel regions in the plurality of first units E1 arranged along the second direction DR2 may alternately have the first arrangement and the second arrangement, and the sub-pixel regions in the plurality of first units E1 arranged along the first direction DR1 may alternately have the first arrangement order and the second arrangement order. In some embodiments, the sub-pixel regions in the plurality of first units E1 arranged along the first direction DR1 may alternately have the first arrangement and the second arrangement, and the sub-pixel regions in the plurality of first units E1 arranged along the second direction DR2 may alternately have the first arrangement order and the second arrangement order. The arrangement design of the sub-pixel regions in other display panels (such as the second display panel DP2) of the tiled display device TD may be the same as the arrangement design of the sub-pixel regions in the first display panel DP1, and will not be redundantly described.

Through the arrangement design of the sub-pixel regions mentioned above, after the first display panel DP1 and the second display panel DP2 are rotated (for example, the second display panel DP2 is rotated by 180 degrees, but not limited thereto) and tiled to form the tiled display device TD, the plurality of first units E1 may include a first repeating unit RU1, and the plurality of second units E2 may include a second repeating unit RU2. The sub-pixel regions in the first repeating unit RU1 have the first arrangement mentioned above, and the sub-pixel regions in the second repeating unit RU2 have the second arrangement mentioned above. Specifically, the first display portion A1 of the first display panel DP1 includes a plurality of first repeating units RU1 and a plurality of second repeating units RU2, or in other words, the first display portion A1 is composed of the plurality of first repeating units RU1 and the plurality of second repeating units RU2. Similarly, the second display portion A2 of the second display panel DP2 includes a plurality of first repeating units RU1 and a plurality of second repeating units RU2, or in other words, the second display portion A2 is composed of the plurality of first repeating units RU1 and the plurality of second repeating units RU2. In the first display panel DP1 and the second display panel DP2, a first repeating unit RU1 may be adjacent to a plurality of second repeating units RU2 in the first direction DR1 and the second direction DR2. A first repeating unit RU1 and a second repeating unit RU2 may respectively be located at two sides of the tiling edge TP of the tiled display device TD, and the first repeating unit RU1 and the second repeating unit RU2 may form at least a portion of a repeating unit group RB. In detail, as shown in FIG. 8, the repeating unit group RB in the present embodiment may be composed of two first repeating units RU1 and two second repeating units RU2. Specifically, the repeating unit group RB may include two first repeating units RU1 and two second repeating units RU2 arranged in a 2*2 array. For example, the first unit E11, the first unit E12, the second unit E21 and the second unit E22 may form a repeating unit group RB. In such condition, a first repeating unit RU1 (for example, the first unit E11) and a second repeating unit RU2 (for example, the second unit E22) may respectively be located at two sides of the tiling edge TP and may be a portion of the repeating unit group RB. The repeating unit group RB may cross the tiling edge TP, or the repeating unit group RB may extend from the first display panel DP1 to the second display panel DP2. In addition, two first repeating units RU1 (or two second repeating units RU2) may respectively be located at two sides of the tiling edge TP and correspond to each other. In the present embodiment, the first display portion A1 and the second display portion A2 respectively include a plurality of repeating unit groups RB (in FIG. 8, only one repeating unit group RB is indicated in the first display portion A1 and the second display portion A2 as an example). In some embodiments, the first display portion A1 and the second display portion A2 may be respectively composed of a plurality of repeating unit groups RB. For example, the repeating unit groups RB may be arranged in an array to form the first display portion A1 and the second display portion A2.

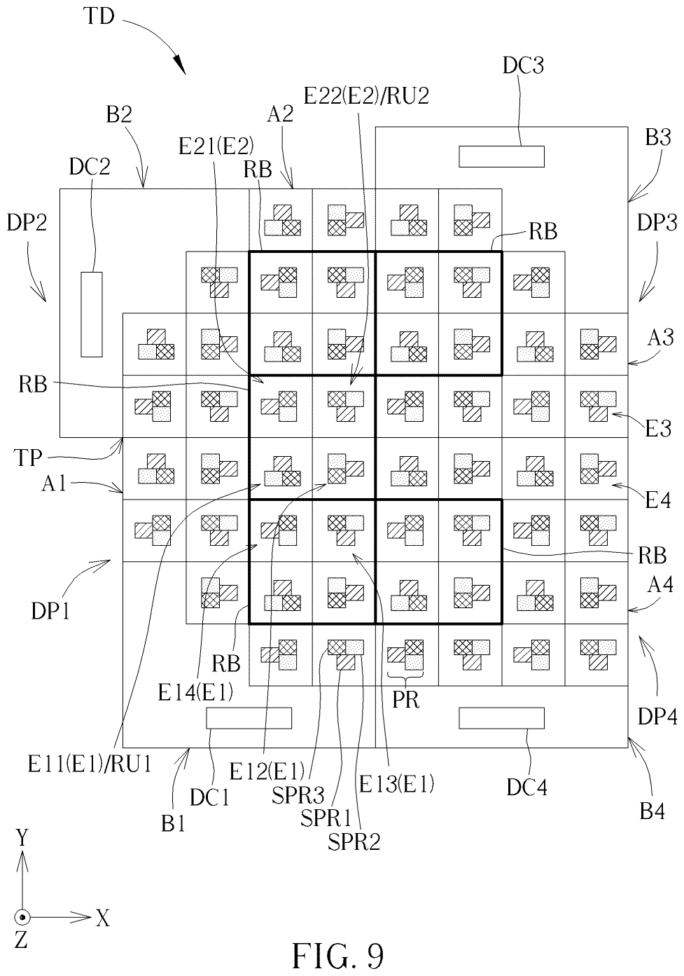

Referring to FIG. 9, FIG. 9 schematically illustrates a top view of a tiled display device according to a fifth embodiment of the present disclosure. According to the present embodiment, the pixel region PR of the first unit E1 of the first display portion A1 of the display panel (for example, the first display panel DP1) in the tiled display device TD may include three sub-pixel regions, that is, the sub-pixel region SPR1, the sub-pixel region SPR2 and the sub-pixel region SPR3. The sub-pixel region SPR1, the sub-pixel region SPR2 and the sub-pixel region SPR3 may be sub-pixel regions of three colors, such as a red sub-pixel region, a green sub-pixel region and a blue sub-pixel region respectively, but not limited thereto. In some embodiments, the pixel region PR may include more than three sub-pixel regions. According to the present embodiment, in the first display panel DP1, the sub-pixel regions in four first units E1 arranged in a 2*2 array may respectively have a first arrangement, a second arrangement, a third arrangement and a fourth arrangement. For example, as shown in FIG. 9, the arrangement of the sub-pixel regions in the first unit E11 may be defined as the first arrangement, the arrangement of the sub-pixel regions in the first unit E12 may be defined as the second arrangement, the arrangement of the sub-pixel regions in the first unit E13 may be defined as the third arrangement, and the arrangement of the sub-pixel regions in the first unit E14 may be defined as the fourth arrangement. The “first arrangement” described herein may represent that the sub-pixel region SPR1, the sub-pixel region SPR2 and the sub-pixel region SPR3 are arranged in a “ [symbol] ” shape (or a pyramid shape or a triangle shape mentioned above), wherein the sub-pixel region SPR1 is located at the top of the “ [symbol] ” shape, and the sub-pixel region SPR2 and the sub-pixel region SPR3 are located at the bottom of the “ [symbol] ” shape, but not limited thereto. In some embodiments, the top of the “ [symbol] ” shape may correspond to the sub-pixel region SPR2 or the sub-pixel region SPR3. The second arrangement may be obtained by rotating the first arrangement by 90 degrees in a clockwise direction, the third arrangement may be obtained by rotating the first arrangement by 180 degrees in a clockwise direction, and the fourth arrangement may be obtained by rotating the first arrangement by 270 degrees in a clockwise direction. In such condition, the first arrangement, the second arrangement, the third arrangement and the fourth arrangement are rotationally symmetric to each other. For example, the first arrangement may respectively be rotationally symmetric to the second arrangement, the third arrangement and the fourth arrangement at a rotation angle of 90 degrees, 180 degrees and 270 degrees. The arrangements of the sub-pixel regions mentioned above may repeatedly appear in the first display panel DP1. In other words, taking any four first units E1 arranged in a 2*2 array in the first display panel DP1, the sub-pixel regions in these four first units E1 may respectively have the first arrangement, the second arrangement, the third arrangement and the fourth arrangement. It should be noted that although the sub-pixel region SPR1, the sub-pixel region SPR2 and the sub-pixel region SPR3 are connected to each other in FIG. 9, it is not limited in the present embodiment. In some embodiments, the sub-pixel region SPR1, the sub-pixel region SPR2 and the sub-pixel region SPR3 may be separated from each other. The arrangement design of the sub-pixel regions in other display panels (such as the second display panel DP2, the third display panel DP3 and the fourth display panel DP4) of the tiled display device TD may be the same as the arrangement design of the sub-pixel regions in the first display panel DP1, and will not be redundantly described.

In the present embodiment, the tiled display device TD may for example be formed by tiling the first display panel DP1, the second display panel DP2, the third display panel DP3 and the fourth display panel DP4. The third display panel DP3 may include a third display portion A3 and a third peripheral portion B3, the third display portion A3 includes a plurality of third units E3, and the third peripheral portion B3 includes a third driving circuit board DC3; the fourth display panel DP4 may include a fourth display portion A4 and a fourth peripheral portion B4, the fourth display portion A4 includes a plurality of fourth units E4, and the fourth peripheral portion B4 includes a fourth driving circuit board DC4. The structure of the third display panel DP3 and the structure of the fourth display panel DP4 may be the same as the structure of the first display panel DP1, and the detail of the structures thereof may refer to FIG. 3 to FIG. 5 and related contents mentioned above. Specifically, in the present embodiment, the first display panel DP1, the second display panel DP2, the third display panel DP3 and the fourth display panel DP4 may be rotated and tiled to form the tiled display device TD, such that the display portions of these display panels may be tiled with each other through the sides not adjacent to the peripheral portions. For example, as shown in FIG. 9, the structure of the second display panel DP2 can be obtained by rotating the structure of the first display panel DP1 by 90 degrees in a clockwise direction, that is, it can be regarded that a first display panel DP1 is rotated by 90 degrees in a clockwise direction and then be tiled with another first display panel DP1. Similarly, the structure of the third display panel DP3 can be obtained by rotating the structure of the first display panel DP1 by 180 degrees. In addition, the arrangement design of the sub-pixel regions in some display panels (for example, the fourth display panel DP4) of the tiled display device TD may be the same as the arrangement design of the sub-pixel regions in the first display panel DP1, but the structure (for example, the size or disposition position of the peripheral portion) of these display panels may be different from the structure of the first display panel DP1, but not limited thereto. It should be noted that the tiling way of the tiled display device TD shown in FIG. 9 may be applied to the embodiments and variant embodiments mentioned above.

Through the arrangement design of the sub-pixel regions mentioned above, in the tiled display device TD, the plurality of first units E1 in the first display panel DP1 may include a first repeating unit RU1, wherein the sub-pixel regions in the first repeating unit RU1 (for example, the first unit E11) have the above-mentioned first arrangement; the plurality of second units E2 may include a second repeating unit RU2, wherein the sub-pixel regions in the second repeating unit RU2 (for example, the second unit E22) have the above-mentioned third arrangement. The first display portion A1 of the first display panel DP1, the second display portion A2 of the second display panel DP2, the third display portion A3 of the third display panel DP3 and the fourth display portion A4 of the fourth display panel DP4 respectively include a plurality of first repeating units RU1 and a plurality of second repeating units RU2. A first repeating unit RU1 and a second repeating unit RU2 may respectively be located at two sides of one of the tiling edges TP of the tiled display device TD, and the first repeating unit RU1 and the second repeating unit RU2 may form at least a portion of a repeating unit group RB. In detail, as shown in FIG. 9, the repeating unit group RB in the present embodiment may for example be composed of the first unit E11, the first unit E12, the second unit E21 and the second unit E22 arranged in a 2*2 array and include a first repeating unit RU1 (that is, the first unit E11) and a second repeating unit RU2 (that is, the second unit E22) respectively be located at two sides of the tiling edge TP (the tiling edge between the first display panel DP1 and the second display panel DP2). The repeating unit group RB may cross the tiling edge TP, or the repeating unit group RB may extend from the first display panel DP1 to the second display panel DP2. The sub-pixel regions in four units (including two first units E1 and two second units E2) of the repeating unit group RB may respectively have the first arrangement, the second arrangement, the third arrangement and the fourth arrangement mentioned above. According to the present embodiment, as shown in FIG. 9, the first display portion A1, the second display portion A2, the third display portion A3 and the fourth display portion A4 respectively include a plurality of repeating unit groups RB (in FIG. 9, only one repeating unit group RB is indicated in each of the display portions as an example). In some embodiments, the first display portion A1, the second display portion A2, the third display portion A3 and the fourth display portion A4 may respectively be composed of a plurality of repeating unit groups RB. For example, the repeating unit groups RB may be arranged in an array to form the first display portion A1, the second display portion A2, the third display portion A3 and the fourth display portion A4. Through the arrangement design of the sub-pixel regions of the present embodiment, the arrangement of the sub-pixel regions near the tiling edge TP may be the same as the arrangement of the sub-pixel regions in other areas (for example, interior of the display panels). Therefore, the situation of mura phenomenon at the tiling edge TP may be reduced, thereby improving the display quality of the tiled display device TD.

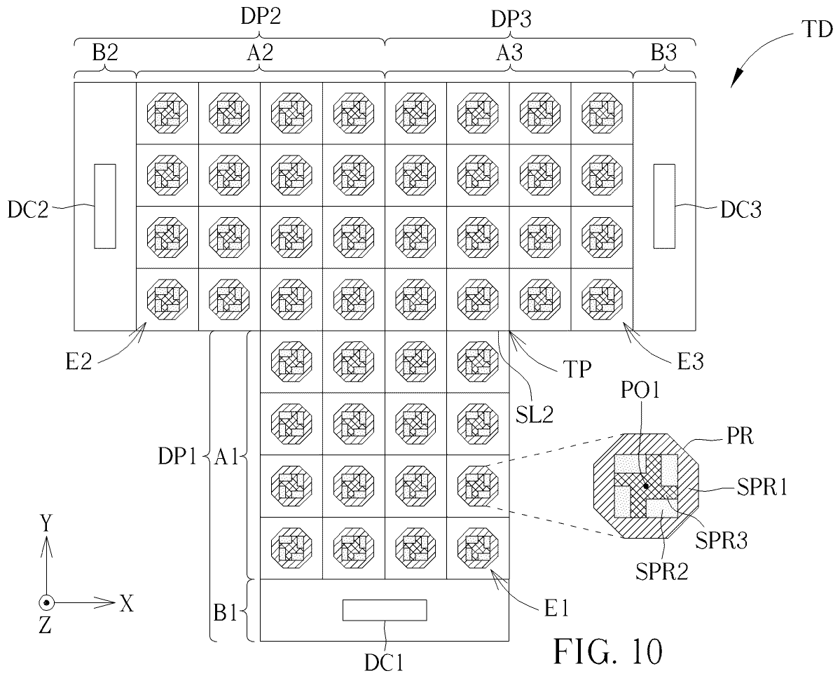

Referring to FIG. 10, FIG. 10 schematically illustrates a top view of a tiled display device according to a sixth embodiment of the present disclosure. In the present embodiment, the pixel region PR of the first unit E1 of the first display panel DP1 in the tiled display device TD may include three sub-pixel regions, that is, the sub-pixel region SPR1, the sub-pixel region SPR2 and the sub-pixel region SPR3. The sub-pixel region SPR1, the sub-pixel region SPR2 and the sub-pixel region SPR3 may be sub-pixel regions of three colors, such as a red sub-pixel region, a green sub-pixel region and a blue sub-pixel region respectively, but not limited thereto. In some embodiments, the pixel region PR may include more than three sub-pixel regions. According to the present embodiment, in a top view direction of the first display panel DP1, the patterns of the three sub-pixel regions in a pixel region PR may have rotational symmetry at a same point (or taking the same point as the center). For example, as shown in FIG. 10, in a top view direction of the first display panel DP1, the pattern of the sub-pixel region SPR3 may be a windmill or a dart, wherein the shape of the sub-pixel region SPR3 may have rotational symmetry by taking a point PO1 as center. The sub-pixel region SPR2 may be disposed to surround the sub-pixel region SPR3. Specifically, the sub-pixel region SPR3 and the sub-pixel region SPR2 may be disposed in a rectangular region (for example, a square region), wherein the shape of the rectangular region has rotational symmetry by taking the point PO1 as center. The sub-pixel region SPR2 is disposed in other regions of the rectangular region except the sub-pixel region SPR3. In such condition, the pattern of the sub-pixel region SPR2 may also have rotational symmetry by taking the point PO1 as center. The sub-pixel region SPR1 may be disposed to surround the sub-pixel region SPR3 and the sub-pixel region SPR2, and the shape of the outer edge of the sub-pixel region SPR1 may be a regular polygon (for example, a regular octagon), wherein the pattern of the sub-pixel region SPR1 may have rotational symmetry by taking the point PO1 as center. In other words, the shape of the sub-pixel region SPR1, the shape of the sub-pixel region SPR2 and the pattern of the sub-pixel region SPR3 all have rotational symmetry by taking the point PO1 as center. It should be noted that although the sub-pixel region SPR1, the sub-pixel region SPR2 and the sub-pixel region SPR3 are connected to each other in FIG. 10, it is not limited in the present embodiment. In some embodiments, the sub-pixel region SPR1, the sub-pixel region SPR2 and the sub-pixel region SPR3 may be separated from each other. In such condition, a region not a sub-pixel region may be included between the sub-pixel region SPR1 and the sub-pixel region SPR2 and between the sub-pixel region SPR2 and the sub-pixel region SPR3. In addition, the disposition ways and patterns of the sub-pixel regions shown in FIG. 10 are exemplary, and are not limited in the present disclosure. In other embodiments, the sub-pixel region SPR1, the sub-pixel region SPR2 and the sub-pixel region SPR3 may respectively include other suitable patterns, such that the patterns of the sub-pixel region SPR1, the sub-pixel region SPR2 and the sub-pixel region SPR3 may have rotational symmetry by taking the same point (such as the point PO1) as center. The pattern design of the sub-pixel regions in other display panels (for example, the second display panel DP2 and the third display panel DP3) of the tiled display device TD may be the same as the pattern design of the sub-pixel regions in the first display panel DP1, and will not be redundantly described.

In the present embodiment, the tiled display device TD may be formed by rotating and tiling the first display panel DP1, the second display panel DP2 and the third display panel DP3. For example, the structure of the second display panel DP2 can be obtained by rotating the structure of the first display panel DP1 by 90 degrees in a clockwise direction, that is, it can be regarded that a first display panel DP1 is rotated by 90 degrees in a clockwise direction and then be tiled with another first display panel DP1. Similarly, the structure of the third display panel DP3 can be obtained by rotating the structure of the first display panel DP1 by 90 degrees in a counterclockwise direction. In addition, in the present embodiment, a side of a display panel may be used for tiling with a plurality of display panels. For example, as shown in FIG. 10, the side SL2 of the first display panel DP1 may be used for tiling with the second display panel DP2 and the third display panel DP3 at the same time, but not limited thereto. The tiling way of the display panels in the present embodiment may be applied to the embodiments and variant embodiments mentioned above.

Through the pattern design of the sub-pixel regions mentioned above, after the first display panel DP1, the second display panel DP2 and the third display panel DP3 are rotated and tiled to form the tiled display device TD, since the shapes of the sub-pixel regions may have rotational symmetry, the patterns of the sub-pixel regions near the tiling edge TP may be substantially the same as the patterns of the sub-pixel regions in other area (for example, interior of the display panels). Therefore, the situation of mura phenomenon at the tiling edge TP may be reduced, thereby improving the display quality of the tiled display device TD.

In summary, a display panel and a tiled display panel formed of the display panel are provided by the present disclosure, wherein the arrangements or patterns of the sub-pixel regions in the display panel may be designed (for example, making the arrangements or patterns of the sub-pixel regions have rotational symmetry), such that the possibility that mura phenomenon at the tiling edge of the tiled display device is observed by the user may be reduced, thereby improving the display quality of the tiled display device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. A display device, comprising:
a first panel having a first display portion, wherein the first panel comprises:
a plurality of first units disposed in the first display portion, wherein at least one of the plurality of first units comprises:
a pixel region comprising a first sub-pixel region, a second sub-pixel region, a third sub-pixel region, a fourth sub-pixel region, a fifth sub-pixel region and a sixth sub-pixel region, wherein the first sub-pixel region is electrically connected to the second sub-pixel region, the third sub-pixel region is electrically connected to the fourth sub-pixel region, and the fifth sub-pixel region is electrically connected to the sixth sub-pixel region,
wherein the first sub-pixel region, the third sub-pixel region and the fifth sub-pixel region respectively have at least one light emitting unit, and the second sub-pixel region, the fourth sub-pixel region and the sixth sub-pixel region are spare sub-pixel regions;
wherein the first sub-pixel region, the third sub-pixel region and the fifth sub-pixel region have an arrangement sequence in a first direction, and the second sub-pixel region, the fourth sub-pixel region and the sixth sub-pixel region have the arrangement sequence in a direction opposite to the first direction.

2. The display device of claim 1, wherein in a second direction perpendicular to the first direction, the first sub-pixel region is adjacent to the sixth sub-pixel region, the second sub-pixel region is adjacent to the fifth sub-pixel region, and the third sub-pixel region is adjacent to the fourth sub-pixel region.

3. The display device of claim 1, wherein the first sub-pixel region and the second sub-pixel region are connected in parallel with each other, the third sub-pixel region and the fourth sub-pixel region are connected in parallel with each other, and the fifth sub-pixel region and the sixth sub-pixel region are connected in parallel with each other.

4. The display device of claim 1, wherein the first sub-pixel region is a display sub-pixel region of a first color, the second sub-pixel region is a spare sub-pixel region of the first color, the third sub-pixel region is a display sub-pixel region of a second color, the fourth sub-pixel region is a spare sub-pixel region of the second color, the fifth sub-pixel region is a display sub-pixel region of a third color, and the sixth sub-pixel region is a spare sub-pixel region of the third color.

5. The display device of claim 4, wherein the first color, the second color and the third color are red, green and blue respectively.

6. The display device of claim 1, wherein the at least one of the plurality of first units further comprises:
a wire region comprising a plurality of signal lines, wherein at least one of the plurality of signal lines is electrically connected to the pixel region; and
a transparent region adjacent to at least one of the pixel region and the wire region.

7. The display device of claim 6, wherein an area of the transparent region is greater than 33% of an area of one of the plurality of first units.

8. The display device of claim 6, wherein the wire region comprises a plurality of conductive layers, one of the plurality of conductive layers comprises a plurality of conductive portions, and a distance between two adjacent conductive portions among the plurality of conductive portions is greater than or equal to 0.8 micrometers.

9. The display device of claim 6, wherein the wire region comprises a plurality of conductive layers, the plurality of conductive layers comprises a first conductive layer and a second conductive layer located on the first conductive layer and adjacent to the first conductive layer, and in a cross-sectional view of the display device, a portion of the first conductive layer is overlapped with the second conductive layer, and a length of the portion of the first conductive layer is greater than or equal to 0.1 micrometers.

10. The display device of claim 1, wherein the first panel further comprises a first peripheral portion, and the first peripheral portion is not adjacent to at least a side of the first display portion.

11. The display device of claim 1, further comprising a first driving circuit board disposed in the first peripheral portion.

12. A tiled display device having a first display portion, a first peripheral portion, a second display portion and a second peripheral portion, comprising:
a plurality of first units disposed in the first display portion and comprising a first repeating unit;
a plurality of second units disposed in the second display portion and comprising a second repeating unit, wherein the first repeating unit and the second repeating unit form at least a portion of a repeating unit group, and the first repeating unit and the second repeating unit are located at two sides of a tiling edge of the tiled display device respectively;
a first driving circuit board disposed in the first peripheral portion; and
a second driving circuit board disposed in the second peripheral portion,
wherein a plurality of sub-pixel regions in the first repeating unit have a first arrangement, a plurality of sub-pixel regions in the second repeating unit have a second arrangement, and the first arrangement and the second arrangement are rotationally symmetric to each other;
wherein the first display portion and the second display portion respectively comprise a plurality of the repeating unit groups.

13. The tiled display device of claim 12, wherein the first display portion and the second display portion are arranged along a first direction, and a plurality of sub-pixel regions in a portion of the plurality of first units arranged along the first direction alternately have the first arrangement and the second arrangement.

14. The tiled display device of claim 12, wherein the first display portion and the second display portion are arranged along a first direction, and a plurality of sub-pixel regions in a portion of the plurality of first units arranged along a second direction perpendicular to the first direction alternately have the first arrangement and the second arrangement.

15. The tiled display device of claim 12, wherein the plurality of sub-pixel regions in the first repeating unit form a pixel region, and the first repeating unit further comprises:
a wire region comprising a plurality of signal lines, wherein at least one of the plurality of signal lines is electrically connected to the pixel region; and
a transparent region adjacent to at least one of the pixel region and the wire region.

16. The tiled display device of claim 15, wherein an area of the transparent region is greater than 33% of an area of the first repeating unit.

17. The tiled display device of claim 15, wherein the wire region comprises a plurality of conductive layers, one of the plurality of conductive layers comprises a plurality of conductive portions, and a distance between two adjacent conductive portions among the plurality of conductive portions is greater than or equal to 0.8 micrometers.

18. The tiled display device of claim 15, wherein the wire region comprises a plurality of conductive layers, the plurality of conductive layers comprises a first conductive layer and a second conductive layer located on the first conductive layer and adjacent to the first conductive layer, and in a cross-sectional view of the tiled display device, a portion of the first conductive layer is overlapped with the second conductive layer, and a length of the portion of the first conductive layer is greater than or equal to 0.1 micrometers.

19. The tiled display device of claim 12, wherein a plurality of sub-pixel regions in one of the plurality of first units comprises a first sub-pixel region, a second sub-pixel region and a third sub-pixel region, and a pattern of the first sub-pixel region, a pattern of the second sub-pixel region and a pattern of the third sub-pixel region have rotational symmetry at a same point.

20. The tiled display device of claim 12, wherein the tiled display device further has a third display portion and a third peripheral portion, and the third display portion contacts the first display portion and the second display portion.
